(19) United States
(12) Patent Application Publication
(10) Pub. No.: US 2010/0099240 A1
(43) Pub. Date: Apr. 22, 2010

(54) DICING/DIE-BONDING TAPE AND METHOD FOR MANUFACTURING SEMICONDUCTOR CHIP

(76) Inventors: Kouji Watanabe, Osaka (JP); Kazuyuki Shohara, Osaka (JP); Shota Matsuda, Osaka (JP); Masateru Fukuoka, Osaka (JP); Yoshiyuki Takebe, Osaka (JP)

Correspondence Address: Cheng Law Group, PLLC, 1100 17th Street, N.W., Suite 503, Washington, DC, 20036, US

(21) Appl. No.: 12/374,285

(22) PCT Filed: Jul. 19, 2007
(86) PCT No.: PCT/JP2007/064239

§ 371 Date: Nov. 17, 2009

(30) Foreign Application Priority Data
Jul. 19, 2006 (JP) 2006-197187
Sep. 20, 2006 (JP) 2006-254260
Nov. 13, 2006 (JP) 2006-306700
Nov. 17, 2006 (JP) 2006-311143
Apr. 19, 2007 (JP) 2007-110270

(51) Int. Cl. H01L 21/78; B32B 33/00; B32B 27/30; B32B 5/16

(52) U.S. Cl. 438/464; 428/343; 428/355 AC; 428/323; 428/354; 257/E21.599

(57) ABSTRACT

Obtained is a dicing and die bonding tape that makes it possible to pick up a semiconductor chip easily and reliably in dicing a semiconductor wafer to pickup the semiconductor chip together with the whole die bonding film. A dicing and die bonding tape used in dicing of a wafer, in obtaining a semiconductor chip, and in die bonding of the semiconductor chip, the dicing and die bonding tape having a die bonding film 3, and a non pressure sensitive adhesive film 4 bonded on one surface of the die bonding film 3, the separation strength between the die bonding film 3 and the non pressure sensitive adhesive film 4 being within a range of 1 to 6 N/m, the shear strength between the die bonding film 3 and the non pressure sensitive adhesive film 4 being 0.3 to 2 N/mm².

### TECHNICAL FIELD

The present invention relates to a dicing and die bonding tape used for manufacturing semiconductor chips. In detail, the present invention relates to a dicing and die bonding tape to be bonded to a semiconductor wafer, and to be used in dicing and in die bonding and also to a method for manufacturing the semiconductor chip using the dicing and die bonding tape.

### BACKGROUND ART

Conventionally, dicing and die bonding tapes have been used in order to cut semiconductor chips from semiconductor wafers, and to mount the semiconductor chips on a substrate etc. The semiconductor wafer is bonded on one surface of a die bonding film, a dicing film is bonded on a surface opposite to the above-described surface of the die bonding film. In dicing, the semiconductor wafer is diced together with the die bonding film. After the dicing, the die bonding film is separated from the dicing film, and the semiconductor chip is removed together with the die bonding film. Then, the semiconductor chip is mounted on a substrate from the die bonding film side.

In order to perform reliable and stable dicing, strong bonding of the semiconductor wafer to the dicing film is necessary. At the same time, easy separation of the semiconductor chip and the die bonding film having the semiconductor chip bonded thereto from the dicing film needs be secured in pickup of the semiconductor chip after the dicing. For this object, dicing films and dicing and die bonding films using pressure sensitive adhesives that is curable with irradiation of ultraviolet rays, radioactive rays, or light have been known. The pressure sensitive adhesive power of this kinds of dicing films and dicing and die bonding films may be lowered by curing of the pressure sensitive adhesive caused by irradiation with ultraviolet rays, radioactive rays, or light, after dicing.

For example, the following patent document 1 discloses a dicing and die bonding tape having a radiation curing type pressure sensitive adhesive layer laminated on one surface of the film adhesive layer. The film adhesive layer includes: (A) a thermoplastic resin, and (B) a film adhesive that includes an epoxy resin having an epoxy resin with not less than 3 of organic functionalities and a liquid epoxy resin at a specific proportion. This film adhesive layer is the die bonding film to be bonded on one surface of the semiconductor element, and the radiation curing type pressure sensitive adhesive layer is the dicing film.

On the other hand, for example, the following patent document 2 discloses a die bonding and dicing tape having a radiation curing type pressure sensitive adhesive layer including a pressure sensitive adhesive and a radiation polymerizable oligomer, and a die bonding film layer, the layers being formed on a substrate in this order. The modulus of elasticity after radiation curing of the radiation curing type pressure sensitive adhesive layer as a dicing film is 0.1 to 10 MPa, and the modulus of elasticity of the die bonding film layer is 10 to 2000 MPa at 25° C., and 3 to 50 MPa at 260° C.

The following patent document 3 discloses a die bonding and dicing tape having a radiation curing type pressure sensitive adhesive layer, and a die bonding film layer on a substrate, the layers being formed in this order. The modulus of elasticity after radiation curing of the radiation curing type pressure sensitive adhesive layer as a dicing film is 0.1 to 10 MPa, the water absorption of the die bonding film layer is not more than 1.5% by volume, and the modulus of elasticity at 250° C. is not more than 10 MPa.

In the die bonding and dicing tapes as described in the patent documents 1 to 3, the die bonding film layer is bonded on the semiconductor wafer, a semiconductor chip is obtained after dicing, and then the pressure sensitive adhesive layer is cured by irradiation with radioactive rays of the radiation curing type pressure sensitive adhesive layer. Subsequently, the die bonding film layer having the semiconductor chip bonded thereto is separated from the radiation curing type pressure sensitive adhesive layer, whereby the semiconductor chip is picked up.

Furthermore, the following patent document 4 discloses an ultraviolet curing type dicing and die bonding tape. Here, the first substrate film, a pressure sensitive adhesive layer, the second substrate film, and a die bonding film are laminated in this order. The die bonding film is formed using an ultraviolet curing type resin. Here, a semiconductor wafer is bonded to the surface of the die bonding film, and dicing is performed. After dicing, the die bonding film is irradiated with ultraviolet rays to be cured, and then a semiconductor chip is removed together with the cured film adhesive.

Patent document 1: JP, 2004-292821,A
Patent document 2: JP, 2002-226796,A
Patent document 3: JP, 2002-158276,A
Patent document 4: JP, 2004-349510,A

### DESCRIPTION OF THE INVENTION

However, in case of use of a pressure sensitive adhesive or a die bonding film curable by irradiation of radioactive rays or ultraviolet rays as described in patent documents 1 to 4, reduction of the pressure sensitive adhesive power or the adhesive strength by irradiation of ultraviolet rays or radioactive rays was needed. Therefore, implementation of complicated processes of irradiation of ultraviolet rays or radioactive rays was needed. Furthermore, facilities for irradiation of ultraviolet rays or radioactive rays was also needed. Furthermore, the ultraviolet curing type resin, and the resin of forming the radiation curing type pressure sensitive adhesive layer were comparatively expensive, resulting in inevitable higher manufacturing costs.

Furthermore, the dicing and die bonding tapes using the radiation curing type pressure sensitive adhesive described in the patent documents 1 to 3 had comparatively soft radiation curing type pressure sensitive adhesive layers in dicing. Therefore, the tapes had insufficient cutting ability in dicing, and thereby easily gave hairy cutting waste in pickup of the semiconductor chip after dicing, resulting in failure in pickup of the semiconductor chips. In addition, attaching of the hairy cutting waste to the die bonding film or the semiconductor chip sometimes failed to mount the picked-up semiconductor chips with high precision and in a desired direction.

Furthermore, in recent years, thinner semiconductor wafers are needed, and accordingly dicing using a laser is now being widely used. In dicing using irradiation of a laser, irradiation of the laser beam causes reaction of the pressure sensitive adhesive curable with ultraviolet rays, radioactive rays, etc., leading to possible welding of the pressure sensitive adhesive to the die bonding film. Welding of the dicing film including such a pressure sensitive adhesive to the die bonding film may lead to completely impossible pickup of the diced semiconductor chip.

Alternatively, irradiation of radioactive rays might not sufficiently reduce the pressure sensitive adhesive power of the radiation curing type pressure sensitive adhesive. In this case, attempt of separation of the die bonding film having the semiconductor chip bonded thereto from the radiation curing type pressure sensitive adhesive layer tended to apply excessive force to the semiconductor chip, resulting in possible breakage of the semiconductor chip.

Also in the dicing and die bonding tape having the die bonding film using the ultraviolet curing type resin described in the patent document 4, even curing by UV irradiation of the die bonding film might not sufficiently reduce the pressure sensitive adhesive power of the die bonding film. Accordingly, the dicing and die bonding tape sometimes failed to secure easy and smooth separation of the semiconductor chip together with the die bonding film as in case of the patent documents 1 to 3. For this reason, there was a possibility that an excessive force applied to the semiconductor chip might damage the semiconductor chip.

In consideration of the present circumstances of the above-described conventional technologies, an object of the present invention is to provide a dicing and die bonding tape enabling easy and reliable pickup of a semiconductor chip together with the die bonding film without complicated operations of irradiation of ultraviolet rays, light, etc., in dicing of a semiconductor wafer, and in subsequent pickup of the semiconductor chip together with the die bonding film, and to provide a method for manufacturing the semiconductor chip using the dicing and die bonding tape.

The present invention provides a dicing and die bonding tape used in dicing of a wafer, in obtaining a semiconductor chip, and in die bonding of the semiconductor chip, the dicing and die bonding tape comprising: a die bonding film, and a non pressure sensitive adhesive film bonded on one surface of the die bonding film, a separation strength between the die bonding film and the non pressure sensitive adhesive film being within a range of 1 to 6 N/m, a shear strength between the die bonding film and the non pressure sensitive adhesive film being 0.3 to 2 N/mm².

A dicing film is bonded on a surface opposite to the surface of the above-described non pressure sensitive adhesive film having the die bonding film bonded thereon, and thus the dicing is performed. The “dicing and die bonding tape” in the present invention designates a tape used for dicing and die bonding. The dicing and die bonding tape includes the above-described die bonding film and the non pressure sensitive adhesive film as indispensable constitutional elements, and may have or may not have the dicing film. When the dicing and die bonding tape does not have the dicing film, a dicing film is separately prepared to be bonded in dicing, and thus dicing is performed. In this case, since the dicing and die bonding tape is used in dicing, it is regarded as a dicing and die bonding tape.

In a specific aspect of the dicing and die bonding tape of the present invention, the elongation in a point of tensile rupture of the non pressure sensitive adhesive film is within the range of 10 to 100%, or within the range of 580 to 1200%.

In another specific aspect of the dicing and die bonding tape of the present invention, the modulus of elasticity of the non pressure sensitive adhesive film at a temperature in pickup is within the range of 1 to 400 MPa.

Instill another specific aspect of the dicing and die bonding tape of the present invention, the storage elastic modulus of the non pressure sensitive adhesive film at a temperature in pickup is within the range of 1 to 400 MPa, and the elongation in the above-described point of tensile rupture is within the range of 5 to 100%.

In still another specific aspect of the dicing and die bonding tape of the present invention, the surface energy of the surface bonded on the die bonding film of the non pressure sensitive adhesive film is not more than 40 N/m.

In another specific aspect of the dicing and die bonding tape of the present invention, the non pressure sensitive adhesive film consists of a cured substance by cross-linking of a curable resin composition.

In another specific aspect of the dicing and die bonding tape of the present invention, the principal component of the non pressure sensitive adhesive film is a (meth) acrylic ester polymer having an alkyl group therein, the carbon number of the alkyl group being 1 to 18. More preferably, the acid value of the (meth)acrylic acid ester polymer is not more than 2.

In another specific aspect of the dicing and die bonding tape of the present invention, the non pressure sensitive adhesive film further includes an oligomer having a double-bonding functional group that is reactive with an acrylic group, the weight average molecular weight of the oligomer being in the range of 1000 to 50000, the glass transition temperature Tg being not more than 25° C.

In another specific aspect of the dicing and die bonding tape of the present invention, the oligomer is blended at a proportion of 1 to 100 parts by weight to the (meth) acrylic acid ester polymer 100 parts by weight.

In another specific aspect of the dicing and die bonding tape of the present invention, the oligomer is an acrylic oligomer having one kind of skeleton selected from a group consisting of polyether skeleton, polyester skeleton, butadiene skeleton, polyurethane skeleton, silicate skeleton, and dicyclopentadiene skeleton.

In another specific aspect of the dicing and die bonding tape of the present invention, the acrylic oligomer has acrylic groups at both ends of the molecule thereof.

In another specific aspect of the dicing and die bonding tape of the present invention, the above-described acrylic oligomer is an urethane acrylic oligomer having 3 to 10 of functionality.

In another specific aspect of the dicing and die bonding tape of the present invention, the non pressure sensitive adhesive film further includes filler particles having an average particle diameter of 0.1 to 10 μm.

In another specific aspect of the dicing and die bonding tape of the present invention, the non pressure sensitive adhesive film has a two-layered structure having a first and a second layers laminated thereon. Preferably, the first layer of the non pressure sensitive adhesive film is a layer having a low modulus of elasticity, the modulus of elasticity being 1 to 1000 MPa at 23° C. More preferably, the layer having a low modulus of elasticity is formed using a material including an acrylic resin or a silicone resin.

In another specific aspect of the dicing and die bonding tape of the present invention, the dicing film is bonded on a surface opposite to a surface having the die bonding film of the non pressure sensitive adhesive film bonded thereto.

In the dicing and die bonding tape according to the present invention, the die bonding film preferably consists of a composition containing an epoxy compound, a macromolecule polymer having an epoxy group, and an acid anhydride curing agent.

The method for manufacturing a semiconductor chip of the present invention is a method for manufacturing of a semiconductor chip comprising: a step of preparing a dicing and die bonding tape concerning the present invention, and a semiconductor wafer; a step of bonding the semiconductor wafer on a surface opposite to a surface of the die bonding film having the non pressure sensitive adhesive film bonded thereto of the dicing and die bonding tape; a step of dicing the semiconductor wafer together with the dicing and die bonding tape to divide the semiconductor wafer into an individual semiconductor chip; and a step of separating the semiconductor chip having the die bonding film bonded thereto from the non pressure sensitive adhesive film after the dicing to pick up the semiconductor chip together with the die bonding film.

In the method for manufacturing the semiconductor chip of the present invention, the semiconductor chip is preferably picked up, while avoiding variation of the separation force between the die bonding film and the non pressure sensitive adhesive film, after the dicing.

Here, an expression of “avoidance of varying the separation force”, as used herein, represents, for example, a condition wherein any processing for varying the separation force is not performed, the processings include: variation of the separation force based on reduction of a pressure sensitive adhesive power by curing of either layer of the dicing and die bonding tapes by irradiation of light and/or heating; variation of the separation force by contraction of either of layers; and variation of the separation force by foaming of either of layers.

### EFFECT OF THE INVENTION

In the dicing and die bonding tape concerning the present invention, the non pressure sensitive adhesive film is bonded on the die bonding film, the separation strength between the die bonding film and the non pressure sensitive adhesive film is in the range of 1 N/m to 6 N/m, and the shear strength between the die bonding film and the non pressure sensitive adhesive film is within the range of 0.3 N/m² to 2N/mm². Therefore easier separation of the die bonding film from the non pressure sensitive adhesive film will be attained, while avoiding stringing trouble etc. in the interface between the die bonding film and the non pressure sensitive adhesive film.

In use of the dicing and die bonding tape described to the above-described patent documents 1 to 3, the pressure sensitive adhesive power of the radiation curing type pressure sensitive adhesive layer before UV irradiation was set to be comparatively high. Accordingly, sufficient reduction of the pressure sensitive adhesive power of the radiation curing type pressure sensitive adhesive layer was needed, in separation of the die bonding film from the radiation curing pressure sensitive adhesive layer, and therefore additional time and effort of irradiation with ultraviolet rays for reduction of pressure sensitive adhesive power was needed. Furthermore, the pressure sensitive adhesive power sometimes failed to provide sufficient reduction, even after irradiation with ultraviolet rays

By contrast, in the dicing and die bonding tape of the present invention, in pickup of the semiconductor chip together with the die bonding film after dicing, since the separation strength and the shear strength between the non pressure sensitive adhesive film and the die bonding film are set within the above-described specific range, the die bonding film having the semiconductor chip bonded thereto can be easily separated from the non pressure sensitive adhesive film, while eliminating implementation of any process for varying the separation force. Furthermore, since the above-described separation strength and shear strength are set within the above-described specific range, a phenomenon of the semiconductor chip jumping in a lateral direction in dicing, that is, lateral jump can be suppressed. As a result, breakage of the semiconductor chip may also be suppressed in removal of the semiconductor chip the together with the die bonding film.

In the method for manufacturing of the semiconductor chip concerning the present invention, after the semiconductor wafer having the dicing and die bonding tape of the present invention bonded thereto is diced to be divided into an individual semiconductor chip, the die bonding film having the semiconductor chip bonded thereto is separated from the non pressure sensitive adhesive film, and thus the semiconductor chip is picked up. Thereby, pickup of the semiconductor chip by easy and reliable separation may be attained while avoiding stringing defect etc., leading to prevention of breakage of the semiconductor chip.

In addition, when the semiconductor chip is picked up, while avoiding the variation of the separation force between the die bonding film and the non pressure sensitive adhesive film after dicing, implementation of complicated processes, such as optical irradiation for varying the separation force, is eliminated, resulting in simplification of the manufacturing process of the semiconductor chip, and in reduction of costs.

### BRIEF DESCRIPTION OF THE DRAWINGS

FIG. 1 (a) and (b) are a partially cross-sectioned front sectional view and a partial cross-sectional plan view illustrating the dicing and die bonding tape concerning one embodiment of the present invention;

FIG. 2 is a partial cross-sectional front sectional view illustrating the dicing and die bonding tape concerning another embodiment of the present invention;

FIG. 3 is a partial cross-sectional front sectional view illustrating the dicing and die bonding tape concerning another embodiment of the present invention;

FIG. 4 is a plan view illustrating the semiconductor wafer used for manufacturing of the semiconductor chip;

FIG. 5 is a view for describing a method for manufacturing the semiconductor chip using the dicing and die bonding tape concerning one embodiment of the present invention, and the Figure is a front sectional view illustrating the condition that the semiconductor wafer is mounted on a stage;

FIG. 6 is a view for describing a method for manufacturing the semiconductor chip using the dicing and die bonding tape concerning one embodiment of the present invention, and the Figure is a front sectional view illustrating a condition in bonding the semiconductor wafer to the die bonding film;

FIG. 7 is a view for describing a method for manufacturing the semiconductor chip using the dicing and die bonding tape concerning one embodiment of the present invention, and the Figure is front a sectional view illustrating a condition of having bonded the semiconductor wafer to the die bonding film;

FIG. 8 is a view for describing a method for manufacturing the semiconductor chip using the dicing and die bonding tape concerning one embodiment of the present invention, and the Figure is a front sectional view illustrating a condition of the pressure sensitive adhesive layer with the semiconductor wafer having been turned over, and mounted on another stage;

FIGS. 9 (a) to (d) are views for describing a method for manufacturing the semiconductor chip using the dicing and die bonding tape concerning one embodiment of the present invention, and the Figures are partial cross-sectional front sectional views illustrating stepwise process wherein the semiconductor wafer having the die bonding film bonded thereto is diced, and is divided into an individual semiconductor chip;

FIG. 10 is a front sectional view illustrating the semiconductor chip manufactured using the dicing and die bonding tape concerning one embodiment of the present invention;

FIG. 11 is a view illustrating measurement results of the elongation and stress in point of tensile rupture in MD of the non pressure sensitive adhesive film used in Example 4 and Referential example;

FIG. 12 is a view illustrating measurement results of the elongation and stress in point of tensile rupture in TD of the non pressure sensitive adhesive film used in Example 4 and Referential example; and

FIG. 13 is a partial cross-sectional sectional view for describing a non pressure sensitive adhesive film having a two-layered structure in a modified example of the present invention.

### DESCRIPTION OF NOTATIONS

1 Dicing and die bonding tape
2 Releasing film
2a Upper surface
3 Die bonding film
3a Surface
4 Non pressure sensitive adhesive film
4a, 4b Surface
4A First layer
4B Second layer
5 Dicing film
5a Substrate
5b Pressure sensitive adhesive layer
5C Extended part
6, 7 Protective sheet
11 Dicing and die bonding tape
15 Dicing and die bonding tape
16 Dicing film
21 Semiconductor wafer
21a Surface
21b Back surface
21C Outer peripheral side
22 Stage
23 Dicing ring
24 Stage
31 Semiconductor chip
41 First cutting blade
42 First cutting part
43 Second cutting blade
44 Second cutting part

### BEST MODE FOR CARRYING OUT THE INVENTION

Hereinafter, the present invention will be described with reference to detailed embodiments of the present invention.

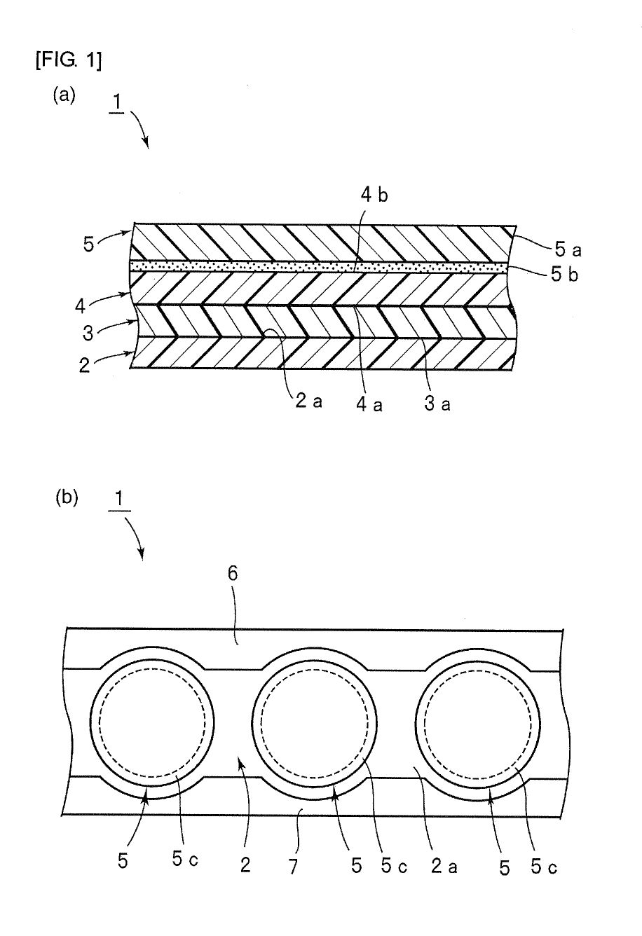

FIGS. 1 (a) and (b) are a partial cross-sectional front sectional view and a partial cross-sectional plan view of the dicing and die bonding tape concerning one embodiment of the present invention.

As illustrated in FIGS. 1 (a) and (b), the dicing and die bonding tape 1 has a long shaped releasing film 2. In the dicing and die bonding tape 1, a die bonding film 3, a non pressure sensitive adhesive film 4, and a dicing film 5 are laminated on an upper surface 2a of the releasing film 2 in this order. The die bonding film 3, the non pressure sensitive adhesive film 4, and the dicing film 5 have a circular planar shape. The dicing film 5 has a larger diameter than those of the die bonding film 3 and the non pressure sensitive adhesive film 4. The surface 3a having the releasing film 2 of the die bonding film 3 bonded thereto is a surface to where the semiconductor wafer is to be attached.

The dicing film 5 has a substrate 5a and a pressure sensitive adhesive layer 5b having a pressure sensitive adhesive applied to one side of the substrate 5a. In the dicing and die bonding tape 1, the dicing film 5 is attached on one side of the non pressure sensitive adhesive film 4 from the pressure sensitive adhesive layer 5b side. The dicing film 5 is indirectly attached on the die bonding film 3 through the non pressure sensitive adhesive film 4.

The dicing film 5 has a diameter larger than the diameter of the die bonding film 3 and the non pressure sensitive adhesive film 4, as mentioned above. The dicing film has an extended part 5C extending over the outer circumferential edge of the die bonding film 3 and the non pressure sensitive adhesive film 4. The entire surface of the extended part 5C is attached on the upper surface 2a of the releasing film by the pressure sensitive adhesive layer 5b. That is, the dicing film 5 is attached onto the upper surface 2a of the releasing film 2 in an area outside of the outer circumferential edge of the die bonding film 3 and the non pressure sensitive adhesive film 4.

The dicing film 5 has a larger diameter than those the die bonding film 3 and the non pressure sensitive adhesive film 4, because a dicing ring is to be attached on the pressure sensitive adhesive 5b positioned in the extended part 5c, in bonding of the semiconductor wafer to the surface 3a of the die bonding film 3.

As illustrated in FIG. 1 (b), a plurality of laminated products consisting of the die bonding film 3, the non pressure sensitive adhesive film 4, and the dicing film 5 are disposed at equal intervals in a machine direction of the long shaped releasing film 2. Protective sheets 6 and 7 are, not necessarily, provided in an upper surface 2a of the releasing film 2 in an area of the side of the dicing film 5. When the protective sheets 6 and 7 are provided, the dicing and die bonding tape 1 is wound around, for example, in a rolled form, and thereby the pressure applied to the dicing film 5 will be reduced by existence of the protective sheets 6 and 7.

Here, the thickness and shape of the releasing film are not in particular limited, and for example, the releasing film may have a structure where one laminated product consisting of the die bonding film, the non pressure sensitive adhesive film, and the dicing film is disposed on the releasing film in a square shape, and may not be wound around in a rolled form as described above. In addition, the thickness or the shape of the die bonding film, the non pressure sensitive adhesive film, and the dicing film are not in particular limited.

The separation strength between the die bonding film and the non pressure sensitive adhesive film is within the range of 1 N/m to 6 N/m, preferably 1 N/m to 6 N/m, and the shear strength between the die bonding film and the non pressure sensitive adhesive film is within the range of 0.3 N/mm² to 2 N/mm². The separation strength and the shear strength between the die bonding film and the non pressure sensitive adhesive film within these specific ranges enables easy separation of the die bonding film from the non pressure sensitive adhesive film, while avoiding reduction of the separation force. Furthermore, breakage of the semiconductor chip will be avoided in dicing of the semiconductor wafer, or removing of the semiconductor chip.

The separation strength less than 1 N/m between the die bonding film and the non pressure sensitive adhesive film provides weaker adhesion strength, and causes the chip-jump in dicing. The separation strength exceeding 6 N/m makes difficult separation from the non pressure sensitive adhesive film of the die bonding film to which the semiconductor chip is bonded. The shear strength less than 0.3 N/mm↑2 between the die bonding film and the non pressure sensitive adhesive film easily causes lateral jump of the chip in dicing. Conversely, the shear strength exceeding 2 N/mm↑2 makes difficult the separation from the non pressure sensitive adhesive film of the die bonding film to which the semiconductor chip was bonded.

The above-described separation strength is measured for by the following methods. First, a surface opposite to the surface on which the non pressure sensitive adhesive film of the die bonding film of the dicing and die bonding tape has been applied is applied on a stainless plate, and then the die bonding film and the stainless plate are sufficiently bonded to obtain a specimen. Then, the specimen is fixed in a direction causing separation in the interface between the non pressure sensitive adhesive film and the die bonding film, and in this condition, the non pressure sensitive adhesive film is separated from the die bonding film by a force applied in a direction making 180° with respect to the above-described interface. The force applied for separation at this point of time is measured for using Shimadzu AGS-100D etc. to give the separation strength.

In measurement of the above-described shear strength, first, the semiconductor chip is bonded onto a surface opposite to a surface on which the non pressure sensitive adhesive film of the die bonding film of the dicing and die bonding tape has been applied, providing a specimen. Subsequently, the specimen is fixed to a glass plate from the non pressure sensitive adhesive film side, or from the side of the dicing film bonded on the non pressure sensitive adhesive film. Then, a shearing force is applied to the die bonding film with the chip using Series 4000 produced by Dage Holdings Limited, and the shear strength between the die bonding film and the non pressure sensitive adhesive film to which the semiconductor chip has been bonded in the specimen is measured for.

The dicing and die bonding tape 1 uses a non pressure sensitive adhesive film 4 in order to set the separation strength and shear strength within the above-described specific range. That is, the non pressure sensitive adhesive film 4 is used as a separation force adjusting film for adjusting the separation force.

Since occurrence of jump of semiconductor chips etc. can be avoided much more effectively in dicing, the dicing film is preferably bonded on the opposite surface with respect to the surface having the die bonding film of the non pressure sensitive adhesive film bonded thereto.

The above-described releasing film 2 is used in order to protect surface 3a having the semiconductor wafer of the dicing film 3 bonded thereto. However, the releasing film does not necessarily need to be used.

The above-described releasing film 2 is not in particular limited, and films having one side with releasing treatment by silicon provided thereto etc. of polyester films, such as polyethylene terephthalate films; polyolefin films, such as polytetrafluoroethylene films, polyethylene film, polypropylene films, polymethylpentene films, and polyvinyl acetate film; plastic films, such as polyvinylchloride films and polyimide films etc. may be mentioned. Especially, since synthetic resin films, such as polyethylene terephthalate film, have outstanding smoothness, thickness accuracy, etc., they are suitably used.

The above-described releasing film may be a single-layered film and may be a multi-layered film. When the releasing film includes laminated product of a plurality of films, two or more kinds of mutually different above-described films may be laminated together.

The above-described die bonding film 3 is used in order to bond semiconductor chips as electronic component chips to substrates etc., and then it is to be cut together with semiconductor wafers in dicing.

The above-described die bonding film 3 includes curing resin compositions etc. including, for example, suitable curing resins. The above-described curable composition before curing is sufficiently flexible, and therefore deforms easily by an external force. However, after bonded to the semiconductor chip, the die bonding film is cured with heating and luminous energy provided thereto strong bonding of the semiconductor chip to adherends, such as substrates, may be attained. The curing resin is not especially limited, and thermoplastic resins, thermosetting resins, photo-curing resins, etc. may be mentioned.

The above-described thermosetting resin is not in particular limited, and for example, epoxy resins, polyurethane resins, etc. may be mentioned. These thermosetting resins may be used independently and two or more kinds may be used in combination.

As the above-described curing resins, hot melt type adhesive resins such as epoxy resins, polyester resins, poly(meth)acrylic acid ester resins having methyl methacrylates or butyl acrylates etc. as principal monomeric units etc. may especially suitably be used.

In using the above-described epoxy resins, a curing resin composition including an epoxy resin, a solid polymer having a functional group reactive to the epoxy resin, and an epoxy resin curing agent are preferably used. Die bonding films including this curing resin composition can improve bonding reliability in semiconductor chip/substrate and between semiconductor chip/semiconductor chip.

The above-described epoxy resin is not in particular limited, and epoxy resins having polycyclic hydrocarbon skeleton in the principal chain are preferred. Use of the epoxy resins having the polycyclic hydrocarbon skeleton in the principal chain provides stiffness to the cured body of the curing resin composition and consequent inhibition of molecular motion, leading to outstanding mechanical strength and thermal resistance, and improved moisture resistance.

The above-described epoxy resins having polycyclic hydrocarbon skeleton in the principal chain is not in particular limited, and examples of the epoxy resins include: epoxy resins having a dicyclopentadiene skeleton, such as, phenol novolak epoxy resins etc. with a dicyclopentadienedioxide and dicyclopentadiene skeleton (hereinafter referred to as “dicyclopentadiene type epoxy resin”); epoxy resins having a naphthalene skeleton, such as, 1-glycidyl naphthalene, 2-glycidyl naphthalene, 1,2-diglycidyl naphthalene, 1,5-diglycidyl naphthalene, 1,6-diglycidyl naphthalene, 1,7-diglycidyl naphthalene, 2,7-diglycidyl naphthalene, triglycidyl naphthalene, 1,2,5,6-tetraglycidyl ether naphthalene etc. (hereinafter referred to as “naphthalene type epoxy resin”); tetra hydroxyphenyl ethane type epoxy resins, tetrakis(glycidyloxy phenyl)ethane, 3,4-epoxy-6-methylcyclohexyl methyl-3,4-epoxy-6-methylcyclohexane carbonate etc. Especially, dicyclopentadiene type epoxy resins and naphthalene type epoxy resins are suitably used.

These epoxy resins having polycyclic hydrocarbon skeleton in the principal chain may be used independently, and two or more kinds may be used in combination. In addition, the above-described dicyclopentadiene type epoxy resins and naphthalene type epoxy resins may be used independently, respectively, and both may be used in combination.

Solid polymers having a functional group reactive with the above-described epoxy group is not in particular limited, and, for example, resins having an amino group, a urethane group, an imido group, a hydroxyl group, a carboxyl group, an epoxy group, etc. may be mentioned. Especially, high molecular polymer having an epoxy group are preferred. Use of the high molecular polymer having the epoxy group can improve the flexibility of the cured body of the curing resin composition.

When the epoxy resins having polycyclic hydrocarbon skeleton in the principal chain and the high molecular polymer having the epoxy group are used, improvement in mechanical strength, thermal resistance, and moisture resistance of the cured body of the curing resin composition originating in the epoxy resin having the above-described polycyclic hydrocarbon skeleton in the principal chain may be attained, and at the same time improvement in flexibility will be attained, originating in the high molecular polymer having the above-described epoxy group.

The high molecular polymer having the above-described epoxy group is not in particular limited, as long as it is a high molecular polymer having the epoxy group in the end and/or side chain (pendant position), and for example, acrylic rubbers including an epoxy group, butadiene rubbers including an epoxy group, bisphenol type macromolecule epoxy resins, phenoxy resins including an epoxy group, acrylic resins including an epoxy group, urethane resins including an epoxy group, polyester resins including an epoxy group etc. may be mentioned. Since they can improve mechanical strength and thermal resistance of the cured body of the curing resin composition, especially acrylic resins including an epoxy group are suitably used. High molecular polymers having these epoxy group may be used independently, and two or more kinds may be used in combination.

The above-described curing agent for epoxy resins is not in particular limited, and, for example, thermally curing acid anhydride curing agents, such as trialkyl tetrahydro phthalic anhydride, phenolic curing agents, amine curing agents, latent curing agents, such as dicyandiamide, cationic catalyst type curing agents etc. may be mentioned. These curing agents for epoxy resins may be used independently, and two or more kinds may be used in combination.

Of the above-described curing agents for epoxy resins, thermal curing type curing agents in liquid state at ordinary temperatures, and latent curing agents, such as dicyandiamide, that have polyfunctionality and that exhibit effects by a small amount of addition in terms of equivalency may be preferably used. Use of such curing agents provides a film having flexibility at ordinary temperatures before curing, and has satisfactory handling.

As typical example of the above-described thermal curing type curing agents in liquid state at ordinary temperatures, for example, acid anhydride curing agents, such as methyl tetrahydrophthalic anhydride, methylhexahydrophthalic anhydride, methylnadic anhydride, and trialkyl tetrahydrophthalic anhydride, may be mentioned. Especially, since they have hydrophobicity, methyl nadic anhydride and trialkyl tetrahydrophthalic anhydride are suitably used. These acid anhydride curing agents may be used independently, and two or more kinds may be used in combination.

In order to adjust the curing speed, the physical properties of the cured body, etc., curing accelerating agents may be used together with the above-described curing agents for epoxy resins.

The above-described curing accelerating agents is not in particular limited, and for example, imidazole curing accelerating agents, tertiary amine curing accelerating agents, etc. may be mentioned. Since they facilitate control of the system of reaction for adjusting curing speed, the physical properties of the cured body, etc., especially imidazole curing accelerating agents are suitably used. These curing accelerating agents may be used independently and two or more kinds may be used in combination.

The above-described imidazole curing accelerating agents are not in particular limited, and, for example, 1-cyanoethyl-2-phenylimidazole obtained by protecting the first position of the imidazole with a cyanoethyl group, a product with a trade name of “2 MAOK-PW” (manufactured by Shikoku Chemicals Corp.) obtained by protecting the basicity with isocyanuric acid etc. may be mentioned. These imidazole curing accelerating agents may be used independently, and two or more kinds may be used in combination.

In case of use of the acid anhydride curing agent and the curing accelerating agents, such as, the imidazole curing accelerating agent in combination, the amount of addition of the acid anhydride curing agent is preferably set to a value not more than a theoretically necessary equivalent value with respect to the epoxy group. Excessive amount of addition of the acid anhydride curing agent not less than the necessary amount may possibly make easy chlorine ion to elute from the cured body of the curing resin composition by function of water content. For example, extraction of eluted component using hot water from the cured body of the curing resin composition may reduce the pH value of the resulting extracted water to a value about 4 to 5, leading to a large amount of possible elution of chlorine ion extracted from the epoxy resin.

Here, in case of use of the amine curing agent and the curing accelerating agent, such as imidazole curing accelerating agent in combination, the amount of addition of the amine curing agent is preferably set as an amount not more than the theoretically necessary equivalent value with respect to the epoxy group. Excessive amount of addition of the amine curing agent not less than the necessary amount may possibly make easy chlorine ion to elute from the cured body of the curing resin composition by function of water content. For example, extraction of eluted component using hot water from the cured body of the curing resin composition may increase the pH value of the resulting extracted water to provide basicity, leading to a large amount of possible elution of chlorine ion extracted from the epoxy resin.

The non pressure sensitive adhesive film used as the non pressure sensitive adhesive film 4 is not in particular limited, and various plastic films, such as polyester films, such as polyethylene terephthalate films; polyolefin films, such as polytetrafluoroethylene films, polyethylene films, polypropylene films, polymethylpentene films, and polyvinyl acetate films; polyvinylchloride films; polyimide films; acrylic resin films etc. may be mentioned.

“Non pressure sensitive adhesive film”, as used herein, includes not only a film having a surface without adhesiveness, but a slightly adhesive film that does not develop distinctive adhesive property with respect to light contact with fingers

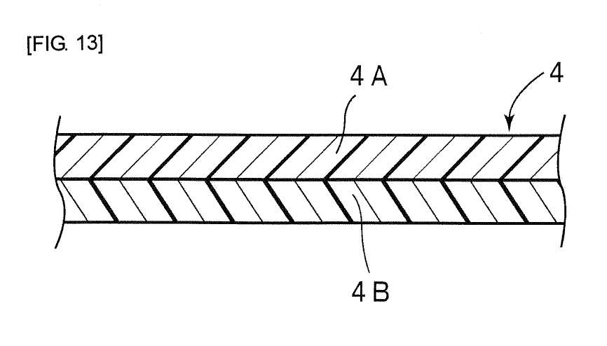

In addition, the above-described non pressure sensitive adhesive film is not necessarily consists of single synthetic resin film, and may be a laminated film obtained by lamination of the first layer 4A and the second layer 4B as schematically illustrated with the non pressure sensitive adhesive film 4 in FIG. 13.

Examples of the above-described polyolefin films include, for example, low density polyethylene (LDP) films, laminated products of LDP film+PP film, laminated products of LDP film+high density polyethylene (HDPE) film, laminated products of LDPE film+HDPE film+LL film, linear low density polyethylene (LLDP) films etc. Of the above-mentioned films, the LLDPE film is preferred, because the separation strength and the shear strength between the die bonding film and the non pressure sensitive adhesive film can be easily set within the above-described specific range, and the film has outstanding expandability at the time of pickup of the semiconductor chip.

In addition, as the above-described acrylic resin films, non pressure sensitive adhesive films including a composition having various acrylic ester polymers as principal components may be used. Acrylic resin films are flexible as compared with polyolefin films, and lowers the modulus of elasticity, easily providing improved cutting ability for dicing. In acrylic resin films, in addition, selection of (meth)acrylic acid ester polymer that is the principal component enables reduction of polarity and modulus of elasticity of the non pressure sensitive adhesive film, and enables easy setting of the above-mentioned of elongation within the preferable range.

The above described (meth)acrylic acid ester polymer is not in particular limited, and (meth)acrylic acid alkyl ester polymers having an alkyl group with a carbon number of 1 to 18, may preferably be used. Use of (meth)acrylic acid alkyl ester polymer including an alkyl group with a carbon number of 1 to 18 can sufficiently lower the polarity and the surface energy of the non pressure sensitive adhesive film, providing improved releasing property. The carbon number exceeding 18 may make solution polymerization difficult. The carbon number of the alkyl group is more preferably not less than 6, thereby resulting in more lowered polarity.

The above-described (meth)acrylic acid ester polymer preferably include polymers obtained by copolymerization of a (meth)acrylic acid alkyl ester monomer that has an alkyl group with a carbon number within the range of 1 to 18 as a main monomer, a monomer including a functional group, and, if needed, other modifying monomer copolymerizable with these monomers, using conventional methods. Of the polymers, the polymers having a carbon number of alkyl group not less than 6 is especially preferred. The weight average molecular weight of the above-described (meth)acrylic acid ester polymer is approximately 200,000 to 2,000,000.

Here, although the above-described other modifying monomers are not in particular limited, it is preferred to avoid use of monomers including a carboxyl group. Use of monomers including a carboxyl group may raise the polarity of the obtained non-pressure sensitive adhesive sheet, and may have resultant adverse effect on pickup property.

In the present invention, “(meth)acrylic acid” designates “methacrylic acid or acrylic acid.”

The above-described (meth)acrylic acid alkyl ester monomer is not in particular limited, and ester monomers obtained by esterification reaction between a primary or secondary alkyl alcohol having a carbon number of alkyl group of 1 to 18, and (meth)acrylic acid are preferred.

Examples of the above-described (meth)acrylic acid alkyl ester monomer include, in detail: methyl (meth)acrylate ethyl(meth)acrylate, propyl(meth)acrylate, isopropyl(meth)acrylate, n-butyl(meth)acrylate, t-butyl (meth)acrylate, 2-ethylhexyl(meth)acrylate, octyl (meth)acrylate, lauryl(meth)acrylate etc.

The above-described (meth)acrylic acid alkyl ester monomer may be used independently, or two or more kinds may be used in combination.

The above-described (meth)acrylic acid ester polymer as a principal component of the above-described acrylic resin film preferably has the acid value not more than 2.

The acid value not more than 2 can easily provide a surface energy not more than 40 N/m.

The method of adjusting the acid value to a value not more than 2 is not in particular limited, and a method of avoiding use of monomers including a carboxyl group as the above-described other monomers, and a method of avoiding hydrolysis of esters in the reaction process may be preferably used.

Here, the acid value, as used herein, designates the number of milligrams of potassium hydroxide needed to neutralize the free acid included in 1 g of (meth)acrylic acid ester polymer.

When the above-described non pressure sensitive adhesive film 4 is an acrylic resin film, an oligomer having a double-bonded functional group reactive with acrylic group, a weight average molecular weight in the range of 500 to 50000, and a glass transition temperature Tg not more than 25° C. are preferably included in addition to the (meth)acrylic acid ester polymer as the above-described principal component. Inclusion of such an oligomer can easily adjust the storage elastic modulus of the non pressure sensitive adhesive film at the temperature in pickup within the range of 1 to 400 MPa, and also can adjust the tensile elongation within the range of 5 to 100%. The molecular weight less than 500 may not demonstrate an effect by blending of the oligomer, and the molecular weight exceeding 50000 excessively raises adhesiveness, leading to possible reduction of the pickup property of the semiconductor chip.

The above-described oligomer is not in particular limited, and oligomers having a skeleton with flexibility, such as, polyether skeleton, polyester skeleton, butadiene skeleton, polyurethane skeleton, silicate skeleton, dicyclopentadiene skeleton etc. are preferred. Here, acrylic oligomers having polyether skeleton or polyester skeleton are more preferred. The skeleton having flexibility represents a skeleton that provides the Tg of the oligomer not more than 25° C. Since they have the skeleton that provides more outstanding flexibility, the acrylic oligomer having polyether skeleton or polyester skeleton are desirable. Polypropylene oxide diacrylates, polyether urethane acrylic oligomers; and M-225 (manufactured by TOAGOSEI CO., LTD.), UN-7600 (manufactured by Negami Chemical Industrial Co., Ltd.), etc. as commercially available items may be mentioned as the acrylic oligomer having the above-described polyether skeleton or polyester skeleton.

The double bonded group reactive with acrylic group is not in particular limited, and acrylic group, methacrylic group, vinyl group, allyl group, etc. may be mentioned. Especially, acrylic group is preferred.

Inclusion of the acrylic group can advantageously achieve the above-described storage elastic modulus and tensile elongation.

It is preferred that not less than 2 of the above-described double bonded group reactive with acrylic group are included.

The above-described 2 of double bonded groups reactive with acrylic group may be included in both ends of the molecule, and may be included in the middle of the chain. Especially, it is preferred that 2 of acrylic groups are included only on both ends of the molecule or the acrylic group is included not only on both ends of molecule but in the middle of chain. That is, polyfunctionality is preferred.

As the above-described polyether skeleton, for example, polypropylene oxide skeleton, polyethylene oxide skeleton, etc. may be mentioned.

As acrylic oligomers having the acrylic group only in both ends of the molecule that has the above-described polyether skeleton, polypropylene oxide diacrylates, polyester urethane acrylic oligomers may be mentioned. Furthermore, as commercially available items (manufactured by Shin-Nakamura Chemical Co., Ltd.), UA340P, UA4200 (manufactured by Shin-Nakamura Chemical Co., Ltd.), Aronix M-1600 (manufactured by TOAGOSEI CO., LTD.), Aronix M-220 (manufactured by TOAGOSEI CO., LTD.), etc. may be mentioned.

Urethane acrylic oligomers having 3 to 10 of functionality may preferably be used as the above-described acrylic oligomer. The urethane acrylic oligomer having a functionality not less than 3 can provide the skeleton with sufficient flexibility, and the urethane acrylic oligomer having a functionality not more than 10 does not provide excessive flexibility with the skeleton. In addition, the urethane acrylic oligomer having a functionality less than 3 demonstrates flexibility, and causes hairy cutting waste in dicing. The urethane acrylic oligomer having functionality exceeding 10 demonstrates brittleness, and may possibly cause pollution in dicing. Urethane acrylic oligomers etc. having polypropylene oxide principal chain may be mentioned as the above-described urethane acrylic oligomers having functionality of 3 to 10. Commercially available items include: U-2PP A, U-4HA, U-6HA, U-15HA, UA-32P, U-324A U-108A, U-200AX, UA-4400, UA-2235PE, UA-160™, UA-6100 (either manufactured by Shin-Nakamura Chemical Co., Ltd.); UN-7600, UN-7700, UN-333, UN-1255 (manufactured by Negami Chemical industrial Co., Ltd.), etc.

The blending proportion of the above-described oligomers is not in particular limited, and for exhibiting effects of the blended oligomers, the amount of the oligomer is preferably not less than 1 part by weight. Excessive amount of the above-described oligomer may not allow dissolution of the raw materials, leading to possible impossibility of manufacturing.

Accordingly, when the above-described oligomers are oligomers having acrylic groups on both ends, the oligomer 1 to 100 parts by weight, more preferably 1 to 50 parts by weight, to (meth)acrylic acid ester polymer 100 parts by weight is preferably used. In the case of the urethane acrylic oligomer having polyfunctionality, preferably used is 1 to 50 parts by weight and more preferably 1 to 30 parts by weight.

The above-described non pressure sensitive adhesive film 4 preferably includes filler particles. Inclusion of the filler particles raises cutting ability, and can suppress attaching of cutting waste onto the pressure sensitive adhesive layer 3 or the semiconductor chip.

The average particle diameter of the above-described filler is preferably 0.1 to 10 μm, and more preferably 0.1 to 5 μm. Excessively large average particle diameter may cause variation in thickness within the surface of the non pressure sensitive adhesive film 4, and excessively small average particle diameter may not provide sufficient improvement in cutting ability.

The above-described fillers are not in particular limited, and silica or alumina may be used.

Especially, synthesized spherical silica fillers is preferred. As commercially available items of such fillers, for example, SC1050MJD, SC2050 MB, SC4050MNA, SC4050MNB, SC4050SEJ (all product manufactured by Admatechs Co., Ltd.), etc. may be mentioned.

The blending proportion of the filler is preferably 0.1 to 150 parts by weight with respect to a total of 100 parts by weight of materials that form the non pressure sensitive adhesive film 4 (excluding the fillers). An excessive blending proportion of the filler may cause breakage of the non pressure sensitive adhesive film 4 at the time of expanding, and an excessive small blending proportion may not provide sufficient improvement in cutting ability.

The non pressure sensitive adhesive film 4 may further include ultraviolet absorbers. Inclusion of the ultraviolet absorber makes possible easier laser dicing of the die bonding film 3.

The above-described non pressure sensitive adhesive film 4 may have a two-layered structure having the first and second layers 4A and 4B, as mentioned above. In this case, use of the mutually different first layer 4A and second layer 4B can easily adjust the physical properties of the non pressure sensitive adhesive film.

When the first layer 4A is disposed on the die bonding film side in the non pressure sensitive adhesive film 4, the first layer 4A preferably has a modulus of elasticity in the range of 1 to 1000 MPa at 23° C. That is, when the first layer 4A is formed of a layer having a low modulus of elasticity with a modulus of elasticity not more than 1000 MPa, pickup workability of the semiconductor chip in the dicing area may be raised. The modulus of elasticity less than 1 MPa may cause poor pickup, in pickup of the semiconductor chip together with the die bonding film after dicing. Alternatively, the modulus of elasticity more than 1000 MPa may easily cause lateral jump of the semiconductor chip mentioned above. The modulus of elasticity of the first layer 4A, at 23° C. that is a layer having a low modulus of elasticity is more preferably not more than 500 MPa.

The first layer 4A that is the above-described layer having a low modulus of elasticity is suitably formed of various materials for forming the above-mentioned non pressure sensitive adhesive film, and of materials having a cross linking structure are preferred. The cross linking structure allows easy separation of the die bonding film from the first layer 4A having the low modulus of elasticity. Therefore, the above-described cross linking structure preferably has a high crosslinking density, and the crosslinking density is desirably not less than 90%. The crosslinking density less than 90% causes migration of sol components etc. in the interface between the die bonding film and the first layer 4A having the low modulus of elasticity, and loses the interface itself, leading to possible drop of pickup property.

In addition, the above-described material for forming the first layer 4A with a low modulus of elasticity is not in particular limited, and various synthetic resin films for forming the above-mentioned non pressure sensitive adhesive film 4 may suitably be used. As such synthetic resins, the above-described polyolefins, acrylic resins, urethane resins, silicone resins, epoxy resins, etc. may be mentioned.

Of the synthetic resins, since lateral jump of the semiconductor chip can be suppressed much more effectively and pickup property can be raised further, acrylic resins having the above-mentioned (meth) acrylic acid ester polymer as a principal component, silicone resins, etc. may preferably be used. Especially, use of the photo-curable acrylic resin composition or the photo-curable silicone resin composition can advantageously simplify the manufacturing process.

In using the photo-curing resin as a material for forming the first layer 4A, the first layer 4A can be easily formed on the substrate layer 5 by applying the material including the photo-curing resin on the substrate layer 5, and then by making the resin cross-linked. Here, formation of the first layer 4A by cross-linking of the photo-curing resin can suppress occurrence of distortion of the first layer 4A by heat.

The thickness of the above-described the first layer 4A is preferably in the range of 0.1 to 30 μm. On one hand, the thickness less than 0.1 μm may not provide sufficient releasing property, and on the other hand the thickness more than 30 μm may make difficult manufacture of the layer having a low modulus of elasticity with uniform thickness. The variation in thickness may not allow suitable execution of dicing in manufacturing of the semiconductor chip.

In the case of the non pressure sensitive adhesive film 4 having the above-described first layer 4A and second layer 4B, the second layer 4B may be formed with suitable synthetic resin materials for forming the above-mentioned non pressure sensitive adhesive film.

In addition, when the first layer 4A is disposed on a side of the die bonding film, the first layer 4A may be formed of a thin pressure sensitive adhesive layer that has slight pressure sensitive adhesiveness, such as EVA, and that has a thickness not more than 10 μm in order to raise close-contacting property to the die bonding film. Here, this pressure sensitive adhesive layer has slight pressure sensitive adhesiveness in a grade wherein the touch with a finger may not provide substantial adherence. The separation force, to the die bonding film, of the pressure sensitive adhesive layer having the slight pressure sensitive adhesiveness preferably does not vary with irradiation of a light.

Here, when the above-described non pressure sensitive adhesive film 4 includes a polyolefin film, the surface roughness on a side of the surface to where the die bonding film 3 is to be bonded is preferably more than 0.15 μm in terms of a surface roughness measured according to JIS B 0601-1994, and more preferably not less than 0.2 μm.

The above-described surface roughness may be measured, for example using a highly precise shape measuring system KS-1100 produced by KEYENCE CORP.

The surface roughness more than 0.15 μm can provide easy separation of the die bonding film 3 from the non pressure sensitive adhesive film 4 in the interface between the die bonding film 3 and the non pressure sensitive adhesive film 4, resulting in implementation of outstanding pickup property. This outstanding pickup property is probably caused by the action of the projection and depression as a base point for separation. In this way, lateral jump of the semiconductor chip in dicing of the semiconductor wafer can be avoided, leading to prevention of breakage of the semiconductor chip in removing. Furthermore, the die bonding film 3 can be easily separated from the non pressure sensitive adhesive film 4, independent of variation of the separation force by optical irradiation etc. Since the die bonding film 3 can easily be separates from the non pressure sensitive adhesive film 4, the problem of remaining of a part of the die bonding film 3 in the interface to the non pressure sensitive adhesive film can be avoided, leading to improvement in reliability in manufacturing of the semiconductor chip.

Since the lateral jump of the semiconductor chip can be more reliably avoided in dicing of the semiconductor wafer, the surface roughness of the surface of the non pressure sensitive adhesive film 4 measured according to JIS B0601-1994 is preferably not more than 0.4 μm.

Methods for obtaining a surface roughness of the surface of the non pressure sensitive adhesive film 4 larger than 0.15 μm is not in particular limited, and a method for manufacturing the non pressure sensitive adhesive film, under conditions for achieving the above-described surface roughness, such as an inflation method and a T-die method; a method for involving micro-particles in the non pressure sensitive adhesive film; a method for forming projections and depressions on the surface of the non pressure sensitive adhesive film by fine embossing etc. may be mentioned.

In the method for manufacturing the non pressure sensitive adhesive film using the above-described inflation method or T-die method, control of membrane formation conditions can provide surface roughness to the surface of the non pressure sensitive adhesive film 4.

The elongation at the point of tensile rupture of the above-described non pressure sensitive adhesive film 4 is within the range of 10 to 100%, and preferably within the range of 580 to 1200%. In this case, when the non pressure sensitive adhesive film 4 includes a polyolefin film, this film is obtained by extrusion, and therefore the elongation at the point of tensile rupture in MD is preferably set within the range of the above-described specification.

The elongation at the point of tensile rupture of the non pressure sensitive adhesive film 4 within the range of 10 to 100% or within the range of 580 to 1200% raises cutting ability. That is, a part of the non pressure sensitive adhesive film 4 is also to be diced, in dicing of the semiconductor wafer into an individual semiconductor chip and in pickup together with the die bonding film. However, here the non pressure sensitive adhesive film 4 has outstanding cutting ability in this time, causing little hairy cutting waste. Accordingly, the semiconductor chip can be picked up without any difficulty, and therefore reliable mounting in a desired direction with respect to the substrate can be achieved. Furthermore, attaching of hairy cutting waste to the die bonding film or the semiconductor chip can reliably be suppressed, leading to high reliability of the semiconductor chip.

Less than 10% of elongation of the above-described point of tensile rupture may cause problems in handling during manufacturing process, or may not provide sufficient cutting ability. Alternatively, the elongation exceeding 100% or less than 580% may not allow sufficient elimination of cut waste from the street. Furthermore, the elongation exceeding 1200% of the above-described point of tensile ruptures excessively raises the flexibility of the non pressure sensitive adhesive film, resulting in possible drop of cutting ability. The elongation of the point of tensile rupture is more preferably within the range of 10 to 50%, or within the range of 580 to 1050%.

Method for manufacturing of the long-shaped film for forming the non pressure sensitive adhesive film 4 is not in particular limited, and suitable methods may be selected based on materials to be used. The long-shaped film may be manufactured, for example, by the inflation method and T-die method. When the non pressure sensitive adhesive film 4 is formed by an extrusion method, the machine direction of the film designates MD and the width direction of the film designates TD.

The storage elastic modulus of the above-described non pressure sensitive adhesive film 4 at a temperature in pickup of the semiconductor chip is preferably within the range of 1 to 400 MPa, and the tensile elongation is preferably within the range of 5 to 100%. The storage elastic modulus less than MPa makes the non pressure sensitive adhesive film excessively soft, and may drop the handling property of the non pressure sensitive adhesive film 4 itself. The storage elastic modulus more than 400 MPa may fail to cause the starting point of separation, and may not allow satisfactory pickup of the semiconductor chip. On one hand, less than 5% of the above-described tensile elongation may reduce the handling property of the non pressure sensitive adhesive film 4. On the other hand, the above-described tensile elongation exceeding 100% may easily generate the above-mentioned hairy cutting waste in dicing.

The storage elastic modulus, as used herein, designates a value obtained by measuring the non pressure sensitive adhesive film having a thickness of 0.5 mm and a width of 5 mm cut into a piece having a width of 3 cm for a storage elastic modulus using DVA-200 produced by IT Measurement Company under a condition of 10 Hz and 0.1% of distortion.

The temperature in pickup, as used herein, designates a temperature obtained by measuring an actual temperature of the semiconductor chip using a thermocouple, when the semiconductor chip after dicing is pushed up from another side with a pin in a process of pickup of the semiconductor chip.

The surface energy of the surface to which the die bonding film of the above-described non pressure sensitive adhesive film 4 is to be bonded is preferably not more than 40 N/m. This surface energy allows much easier separation of the non pressure sensitive adhesive film 4 from the die bonding film.

Furthermore, the die bonding film 3 can be separated easily from the non pressure sensitive adhesive film 4 in separation, while avoiding omission of a part of the die bonding film 3, attaching onto the non pressure sensitive adhesive film 4, and remaining therein. Accordingly, the semiconductor chip allowing much more reliable die bonding may be obtained using the die bonding film 3.

The surface energy of the surface of the above-described non pressure sensitive adhesive film 4 is preferably in the range of 30 to 35 N/m. Excessively high surface energy may cause poor separation at the time of pickup, and excessively low surface energy may generate chip jump with hydraulic pressure at the time of dicing.

The surface energy of the surface of the above-described non pressure sensitive adhesive film 4 may be measured based on JIS K 6798, for example, using a wettability reagent.

The above-described non pressure sensitive adhesive film 4 may be formed using materials including photo-curing resins or thermosetting resins.

When a photo-curing resin or a thermosetting resin is used for formation of the above-described non pressure sensitive adhesive film 4, curing with a light or heat using a light responsive initiator and thermal responsive initiator is necessary. The light responsive initiator is not in particular limited, and for example, optical radical generators, optical cation generators, etc. may be used. As thermal responsive initiators, heat radical generators etc. may be mentioned.

The above-described optical radical generators is not in particular limited, and commercially available examples include, for example: IRGACURE 184, IRGACURE 2959, IRGACURE 907, IRGACURE 819, IRGACURE 651, IRGACURE 369, IRGACURE 379 (either manufactured by Ciba Speciality Chemicals); benzoin methyl ether; benzoin ethyl ether; benzoin iso-propyl ether; Lucilin TPO (manufactured by BASF Japan) etc. The above-described heat radical generators include: organic peroxides, such as, cumene hydroperoxide, diisopropylbenzene peroxide, di-t-butyl peroxide, lauryl peroxide, benzoyl peroxide, t-butylperoxyisopropylcarbonate, t-butylperoxy-2-ethylhexanoate, t-amyl peroxy-2-ethylhexanoate etc.; azo compounds, such as,
2,2′-azobis(isobutyronitrile),
1,1′-azobis(cyclohexanecarbonitrile),
2,2′-azobis(2,4-dimethylvaleronitrile),
dimethyl-2,2′-azobis(2-methylpropionate), etc.

As the above-described optical cation development agents, onium salts, such as aromatic diazonium salts, aromatic halonium salts, and aromatic sulfonium salts; and organometallic complexes, such as iron-allene complexes, titanocene complexes, and aryl silanol aluminium complexes may be used.

The method for formation method of the non pressure sensitive adhesive film 4 using materials including the above-described photo-curing or thermosetting resins is not in particular limited, and following methods may be used. A material for forming the non pressure sensitive adhesive film 4 is applied on a releasing film, the material is cured with optical irradiation and/or heating to form the non pressure sensitive adhesive film 4 on the releasing film, and then the releasing film is separated.

The thickness of the above-described non pressure sensitive adhesive film 4 is not in particular limited, and it is preferably 30 to 100 μm. The thickness less than 30 μm may not provide sufficient expandability, and the thickness more than 100 μm may make easy formation of uniform thickness impossible. Variation in thickness may not allow suitable dicing.

When a non pressure sensitive adhesive film is used as the non pressure sensitive adhesive film to be bonded on the die bonding film, the necessity for formation of the non pressure sensitive adhesive film may be eliminated, for example, by reducing the separation force by optical irradiation etc. Therefore, manufacturing of the semiconductor chip may be attained, while avoiding additional operations for reduction of the separation force using optical irradiation etc.

This optical irradiation here designates intentional irradiation of the non pressure sensitive adhesive film with ultraviolet rays etc., excluding a case where the non pressure sensitive adhesive film is exposed under natural light.

The above-described dicing film 5 has, as described above, a substrate 5a, and a pressure sensitive adhesive layer 5b formed on one side of the substrate 5a by application of a pressure sensitive adhesive.

The above-described substrate 5a is not in particular limited, and polyester films, such as polyethylene terephthalate films; polyolefin films, such as polytetrafluoroethylene films, polyethylene films, polypropylene films, polymethylpentene films, and polyvinyl acetate films; plastic films, such as polyvinylchloride films and polyimide films, etc. may be mentioned. Of the above-mentioned films, since they have outstanding expandability and demonstrates smaller environmental load, polyolefin system films may be suitably used.

As long as a separation strength between the non pressure sensitive adhesive film and the dicing film is set to be larger than a separation strength between the die bonding film and the non pressure sensitive adhesive film, the above-described pressure sensitive adhesive layer 5b is not in particular limited, and is formed using pressure sensitive adhesives, such as acrylic, special synthetic rubber, synthetic resin, and rubber adhesives. Especially, since the acrylic pressure sensitive adhesives have excellent removability and advantageous costs as a pressure-sensitive type, they are suitably used.

When the non pressure sensitive adhesive film is not the dicing film, and is a non pressure sensitive adhesive film bonded on the die bonding film, the separation strength between the non pressure sensitive adhesive film and the dicing film needs to be larger than a separation strength between the die bonding film and the non pressure sensitive adhesive film, and the strength needs to be in the range of 1 N/m to 6 N/m.

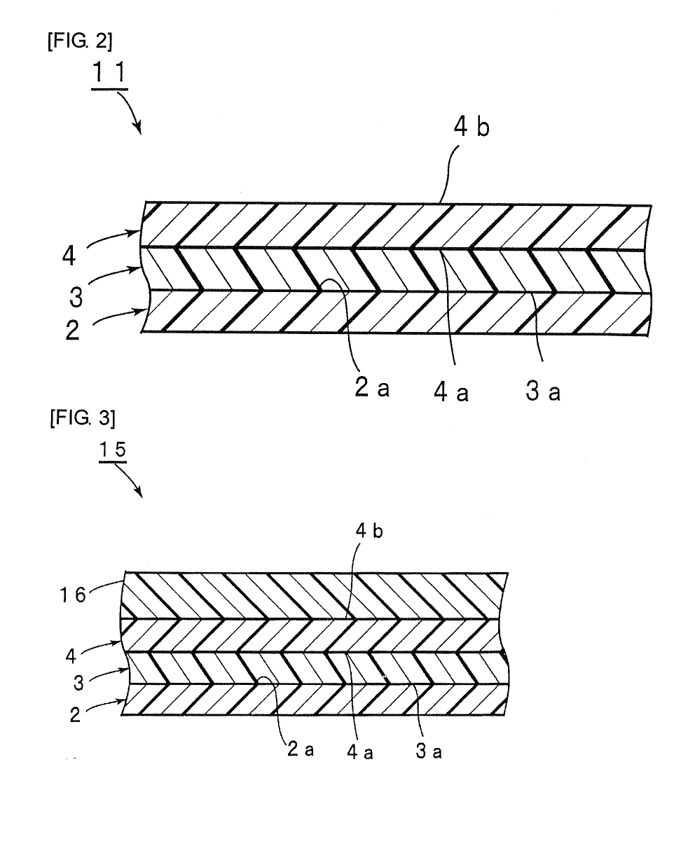

FIG. 2 illustrates the dicing and die bonding tape according to another embodiment of the present invention in a partial cross-sectional front sectional view.

In the dicing and die bonding tape 11 illustrated in FIG. 2, the above-described releasing film 2, the die bonding film 3, and the dicing film 5 as the non pressure sensitive adhesive film of the present invention are laminated in this sequential order. That is, the dicing and die bonding tape 11 is formed like the dicing and die bonding tape 1 except for not having the non pressure sensitive adhesive film 4. In the dicing and die bonding tape 11, the dicing film 5 is corresponding to the non pressure sensitive adhesive film in the present invention.

In the dicing and die bonding tape 11, the separation strength between the die bonding film 3 and the dicing film 5 consisting of the non pressure sensitive adhesive films is set to be not more than 6 N/m, and the shear strength between the die bonding film 3 and the dicing film 5 as the non pressure sensitive adhesive film is set to be not less than 0.3 N/mm².

In this way, as long as the separation strength and the shear strength are in the above-described specific ranges, the dicing film may be used as the non pressure sensitive adhesive film in the present invention. That is, the dicing film consisting of the non pressure sensitive adhesive film may be bonded on one surface of the die bonding film. When the non pressure sensitive adhesive film serves as the dicing film, the die bonding film may be separated from the dicing film in the interface of the die bonding film and the dicing film, leading to easier removing of the semiconductor chip.

Use of the dicing film consisting of the above-described non pressure sensitive adhesive film to be bonded on the die bonding film can eliminate the necessity for formation of the dicing film so as to reduce the separation force, for example, with optical irradiation etc. Accordingly, this method can allow manufacturing of the semiconductor chip, while eliminating additional operations of reducing the separation force with optical irradiation etc.

FIG. 3 illustrates the dicing and die bonding tape according to another embodiment of the present invention in a partial cross-sectional front sectional view.

In the dicing and die bonding tape 15 illustrated in FIG. 3, the above-described releasing film 2, die bonding film 3, non pressure sensitive adhesive film 4, and dicing film 16 are laminated in this sequential order. That is, the dicing and die bonding tape 15 is formed in the same manner as in the dicing and die bonding tape 1 except for having a structure different from that of the dicing film. The dicing and die bonding tape 15 is different from the above-described dicing film 5, and has a dicing film 16 without a pressure sensitive adhesive layer.

The dicing film does not need to have a pressure sensitive adhesive layer. When the dicing film does not have the pressure sensitive adhesive layer, the dicing film is formed, for example, with a material having pressure sensitive adhesive power.

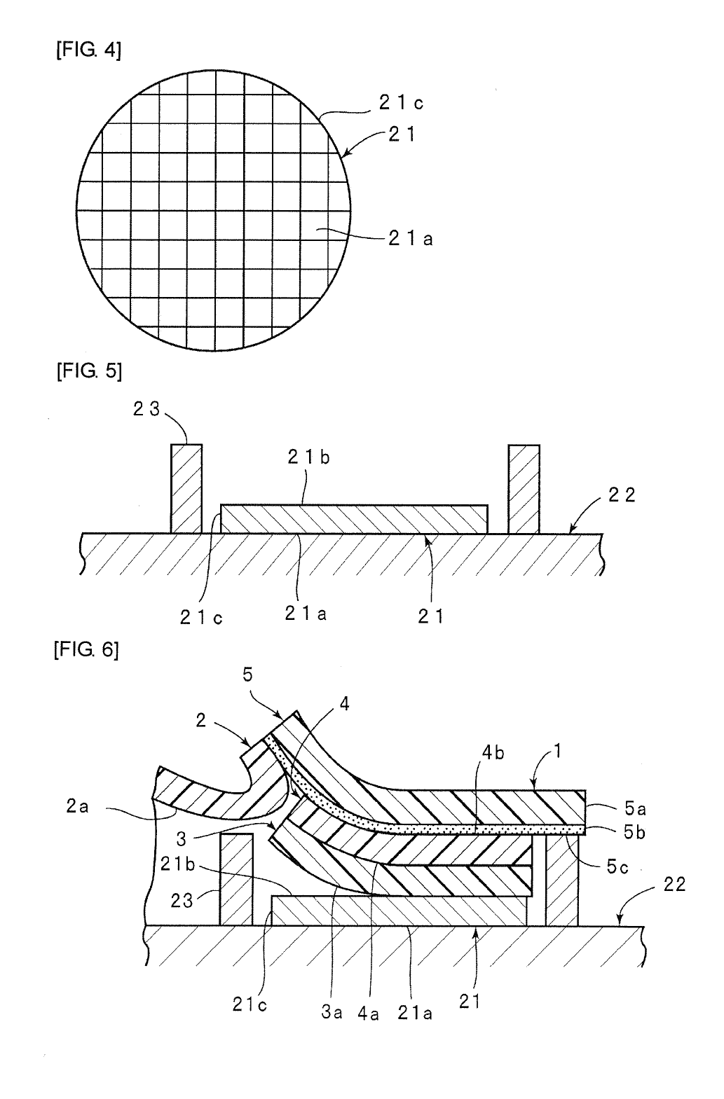

Next, a manufacturing method of the semiconductor chip using the above-described dicing and die bonding tape 1 will be described hereinafter, with reference to FIG. 4 to FIG. 10.

First, the above-described dicing and die bonding tape 1 and semiconductor wafer 21 are prepared.

FIG. 4 illustrates a semiconductor wafer 21 in a plan view. The semiconductor wafer 21 has circular planar shape. Circuits for forming individual semiconductor chip are formed in each area sectioned by a street, not shown, in a matrix form in the surface 21a of the semiconductor wafer 21. The back surface 21b of the semiconductor wafer 21 is ground so that a predetermined thickness may be provided.

The thickness of the semiconductor wafer 21 is preferably not less than 30 μm. The thickness of the semiconductor wafer 21 less than 30 μm generates crack etc. in grinding and handling, leading to possible breakage.

The semiconductor wafer 21 is divided for each area sectioned into a matrix form in dicing mentioned later.

As illustrated in FIG. 5, the prepared semiconductor wafer 21 is mounted reversed on a stage 22. That is, the semiconductor wafer 21 is mounted on the stage 22 so that the surface 21a of the semiconductor wafer 21 may touch the stage 22. A circular dicing ring 23 is provided on the stage 22 in a certain spaced apart relationship with the outer peripheral side 21c of the semiconductor wafer 21. The height of the dicing ring 23 is set equal to or slightly lower than the sum total thickness of the semiconductor wafer 21, the die bonding film 3, and the non pressure sensitive adhesive film 4.

Next, the semiconductor wafer 21 is bonded to the surface 3a of the die bonding film 3 of the dicing and die bonding tape 1. FIG. 6 illustrates the bonding condition of the semiconductor wafer 21 to the die bonding film 3 in a front sectional view.

In the dicing and die bonding tape 1, the dicing film 5 has an extended part 5c extending so as to reach outside the outer circumferential edge of the die bonding film 3 and the non pressure sensitive adhesive film 4. As illustrated in FIG. 6, the exposed pressure sensitive adhesive 5b of the extended part 5c of the dicing film 5 is attached onto the dicing ring 23 while separating the releasing film 2 of the dicing and die bonding tape 1. Furthermore, the exposed die bonding film 3 is bonded to the back side 21b of the semiconductor wafer 21.

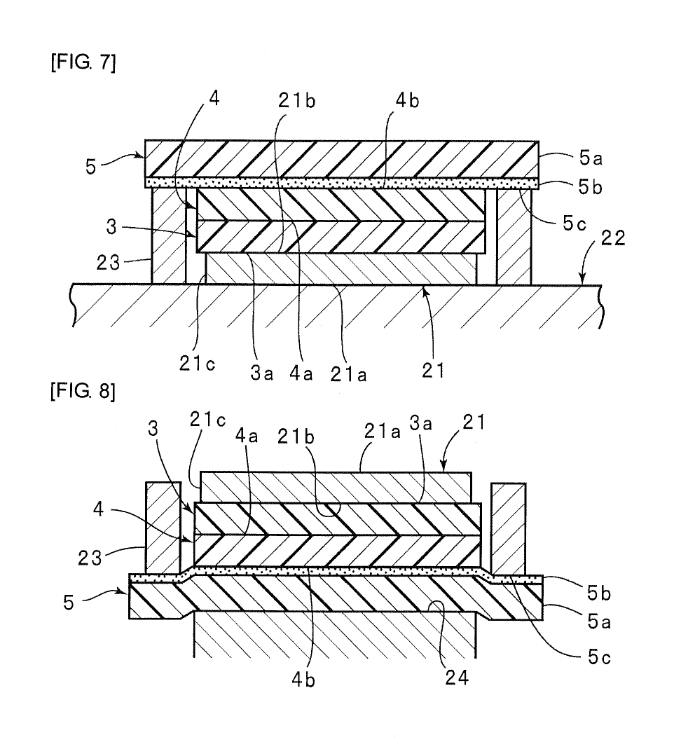

FIG. 7 illustrates the condition of the semiconductor wafer 21 being bonded to the die bonding film 3, in a front sectional view.

The die bonding film 3 is bonded to the entire back side 21b of the semiconductor wafer 21. The extended part 5c of the dicing film 5 is supported by the dicing ring 23 so that application of some additional power may be avoided to the semiconductor wafer 21.

Next, as illustrated in FIG. 8 in a front sectional view, the semiconductor wafer 21 having the die bonding film 3 bonded thereto is removed from the stage 22, and it is turned over. At this time, the dicing ring 23 is removed in a condition of having been attached on the dicing film 5. The removed semiconductor wafer 21 is mounted on another stage 24 so that the surface 21a may face upward.

Next, the semiconductor wafer 21 together with the die bonding film 3 is diced into separate semiconductor chips.

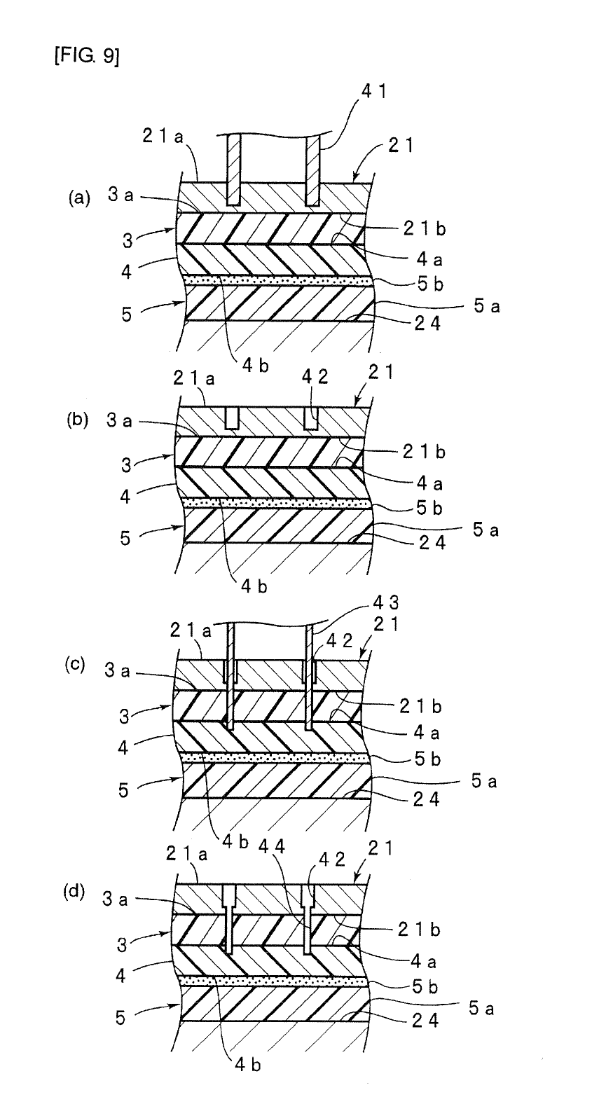

The process of dicing of the semiconductor wafer 21 having die bonding film 3 bonded thereto, and of dividing it into individual semiconductor chip 31 will be described with reference to FIGS. 9 (a) to (d)

FIGS. 9 (a) to (d) illustrate stepwise processes of division into the individual semiconductor chip 31 in a partial cross-sectional front sectional view.

As illustrated in FIGS. 9 (a) to (d), in order to prevent breakage of the semiconductor wafer 21 by dicing, the dicing is performed in two steps (step cut). FIGS. 9 (a) and (b) illustrate the first step of the dicing, and FIGS. 9(C) and (d) illustrate the second step of the dicing. Here, as long as the breakage of the semiconductor wafer 21 in dicing is avoided, the dicing process may be performed in a single step.

As illustrated in FIG. 9 (a), first, the first cutting blade 41 of a dicing apparatus is inserted from the surface 21a of the semiconductor wafer 21, for example, to a position that does not extend to the back surface 21b of the semiconductor wafer 21. After insertion, by retraction of the first cutting blade 41, as illustrated in FIG. 9 (b), the first cutting part 42 will be formed.

Next, as illustrated in FIG. 9 (C), the second cutting blade 43 having a thickness less than the first cutting blade 41 of the dicing apparatus is inserted in the center of the first cutting part 42. The second cutting blade 43 is inserted to a position deeper than the first cutting part 42. The second cutting blade 43 is not limited in particular as long as it penetrates the die bonding film 3, and is inserted to a position so as to avoid penetration of the non pressure sensitive adhesive film 4, for example, to a position not more than half of the thickness of the non pressure sensitive adhesive film 4.

After insertion, when the second cutting blade 43 is retracted, the second cutting part 44 having a cutting width less than the width of the first cutting part 42 will be formed in a position still deeper than the position of the first cutting part 42 as illustrated in FIG. 9 (d)

The dicing method of the semiconductor wafer is not in particular limited, and for example, the methods include a single cut method using one blade; a step cut method using two sheets of cutting blades in sequence; and a bevel cutting method using two sheets of cutting blades, especially a V shaped cutting blade on the surface of the semiconductor wafer etc. Of the methods, the step cut method is suitably performed, from a viewpoint of avoiding breakage of the semiconductor wafer at the time of cutting.

Furthermore, a method by irradiation of laser may be used as the dicing method of the semiconductor wafer. In the case of cutting of the semiconductor wafer by irradiation of a laser beam together with the die bonding film, the laser beam is applied so as to reach the non pressure sensitive adhesive film 4. When the ultraviolet curing type or the radiation curing type conventional dicing film is used, the dicing film induces decomposing reaction by the energy of the laser beam in the dicing by irradiation of the laser beam, leading to a possible problem of welding to the die bonding film. The welding caused makes impossible the pickup of the semiconductor chip from the dicing film.

Alternatively, in this embodiment, since the non pressure sensitive adhesive film 4 cannot easily demonstrate reactivity by irradiation of a laser beam, welding of the die bonding film to the non pressure sensitive adhesive film 4 will hardly to be caused. Accordingly, the semiconductor chip can advantageously be picked up also in dicing using a laser beam.

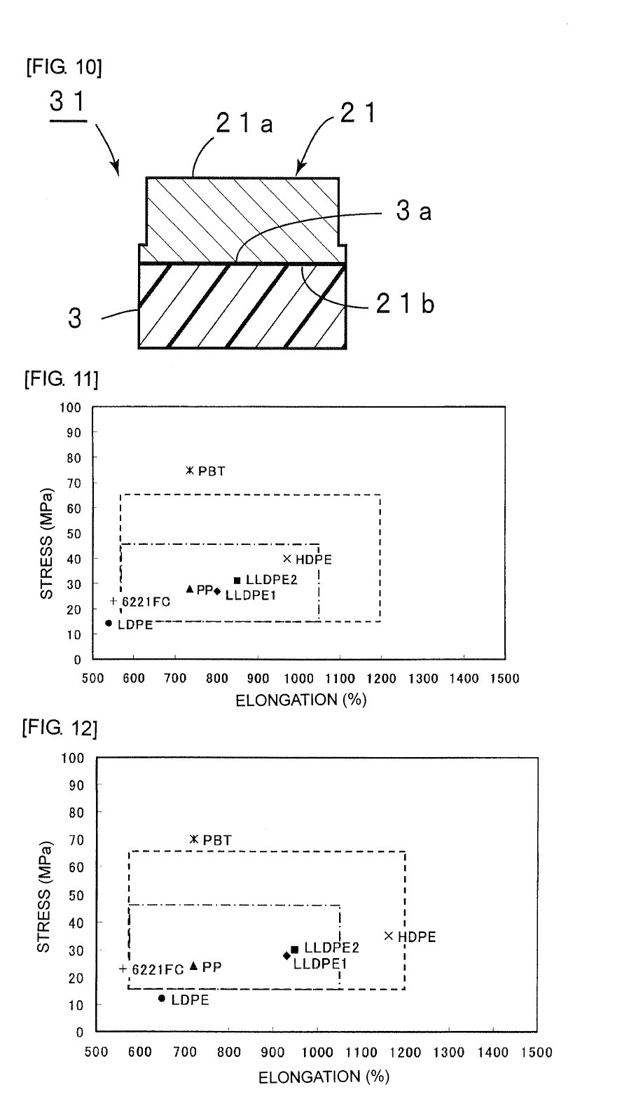

After dicing of the semiconductor wafer and division into the individual semiconductor chips, the spacing between the divided individual semiconductor chips is expanded by enlargement of the dicing film. Subsequently, the die bonding film 3 having the semiconductor chip bonded thereto is separated from the non pressure sensitive adhesive film 4, and thus the semiconductor chip 31 illustrated in FIG. 10 is picked out.

Here, as the method of separation of the die bonding film having the semiconductor chip bonded thereto from the non pressure sensitive adhesive film, a method of pushing up using a large number of pins from the back side of the semiconductor wafer; a method of push up using multiple-stage pin; a method of vacuum-peeling from the surface side of the semiconductor wafer 21; and a method of using supersonic vibration etc. may be mentioned.

For more reliable prevention of breakage of the semiconductor chip 31, the die bonding film having the semiconductor chip bonded thereto is preferably separated from the non pressure sensitive adhesive film by applying a power acting in a direction perpendicularly intersecting to the bonded surface between the semiconductor wafer and the die bonding film.

Although the present invention will, hereinafter, be described in more detail, with reference to Examples, the present invention is not limited only by these Examples.

### Example 1

A blended material was obtained by blending: G-2050M (manufactured by Nippon Oil & Fats Co., Ltd., an acrylic high molecular polymer including epoxy group, weight average molecular weight Mw 200,000) 15 parts by weight; EXA-7200HH (manufactured by DIC Corporation, dicyclopentadiene type epoxy resin) 70 parts by weight; HP-4032D (manufactured by DIC Corporation, naphthalene type epoxy resin) 15 parts by weight; YH-309 (manufactured by Japan Epoxy Resins Co., Ltd., acid anhydride curing agent) 38 parts by weight; 2MAOK-PW (manufactured by Shikoku Chemicals Corporation, imidazole) 8 parts by weight; S320 (manufactured by Chisso Corp., aminosilane) 2 parts by weight; and MT-10 (manufactured by Tokuyama Corp., surface hydrophobed fumed silica) 4 parts by weight. Methyl ethyl ketone (MEEK) as a solvent was added to the blended material to give 60% of solid content. Then the mixture was agitated to obtain a coating liquid.

This coating liquid was applied so as to give a thickness of 40 μm on a releasing film, and was dried by heating in an oven for 3 minute at 110° C. to give a die bonding film formed on the releasing film.

Onto a surface opposite to a side of the releasing film of the die bonding film, 6221FC as a non pressure sensitive adhesive film (a film having a layer of several μm thick of EVA on one side of a polyethylene substrate manufactured by Sekisui Chemical Co., Ltd., total 50 μm of thickness) was laminated from the 6221FC side having the EVA layer laminated thereto, obtaining a laminated material. After the laminated material was cut into a circular shape, PE tape #6318-B as a dicing film (pressure sensitive adhesive film manufactured by Sekisui Chemical Co., Ltd., a rubber pressure sensitive adhesive layer having a thickness of 10 μm is formed on one side of a polyethylene substrate having a thickness of 70 μm) was applied from the pressure sensitive adhesive layer side onto a surface opposite to the die bonding film of the non pressure sensitive adhesive film. The dicing film obtained was cut into a circular shape larger than the size of the die bonding film. In this way, a dicing and die bonding tape in 4 layers having releasing film/die bonding film/non pressure sensitive adhesive film/dicing film laminated in this sequential order was manufactured.

### Example 2

The same method as that in Example 1 was repeated, except for having used an LDPE film (LDPE film obtained by T die extrusion of MIRASON M12 manufactured by Mitsui Chemicals, Inc., extrusion temperature of 200° C., and 50 μm in thickness) as non pressure sensitive adhesive film to obtain a dicing and die bonding tape in 4 layers.

### Example 3

The same method as that in Example 1 was repeated, except for having used (an HDPE film obtained by T die extrusion of HI-ZEX 3300F manufactured by Prime Polymer Co. and Ltd., extrusion temperature of 200° C., and 50 μm in thickness) as non pressure sensitive adhesive film to obtain a dicing and die bonding tape in 4 layers.

### Comparative Example 1

The same method as that in Example 1 was repeated, except for having used GF-8 (a polyolefin film, 50 μm in thickness manufactured by TAMAPOLY CO., LTD.) as non pressure sensitive adhesive film to obtain a dicing and die bonding tape in 4 layers.

### Comparative Example 2

The same method as that in Example 1 was repeated, except for having used an embossed film obtained by pressurizing GF-8 (manufactured by TAMAPOLY CO., LTD. and 50 μm in thickness) to a metal pattern having a pitch of 200 μm, as a non pressure sensitive adhesive film to obtain a dicing and die bonding tape in 4 layers.

### Comparative Example 3

The same method as that in Example 1 was repeated, except for having used a film manufactured by cross-linking of an adhesive layer by irradiation with ultraviolet rays of 2000 mJ to a film manufactured by LINTEC Corp. that is a UV curing type tape: trade name LINTEC D675 in place of the 6221FC (manufactured by Sekisui Chemical Co., Ltd. and 50 μm in thickness) to obtain a dicing and die bonding tape in 4 layers.

Evaluation of Dicing and Die Bonding Tape

(1) Measurement of Separation Strength

A non pressure sensitive adhesive film was laminated on one surface of a die bonding film at 60° C. Next, a stainless steel plate was applied onto a surface opposite to the surface having the non pressure sensitive adhesive film of the die bonding film attached thereto to obtain an evaluation sample. Subsequently, the evaluation sample was fixed so that separation might occur in the interface of the non pressure sensitive adhesive film and the die bonding film. The non pressure sensitive adhesive film was separated from the die bonding film at a separation speed of 300 mm/minute, in a direction making 180° with respect to the interface of the die bonding film and the non pressure sensitive adhesive film. The evaluation sample was measured for a force needed for separation at this time, with a measurement width of 25 mm, using AGS-100D produced by Shimadzu Corporation to obtain an average value as the separation strength.

(2) Measurement of Shear Strength

A Si chip of 3 mm squares and 100 μm in thickness was bonded to one surface of a die bonding film, obtaining a die bonding film having a chip thereon. A non pressure sensitive adhesive film was laminated onto a surface opposite to a surface having a bonding chip of this die bonding film having the chip thereon at 60° C. Next, using a pressure sensitive adhesive double coated tape having a core material of a polypropylene (PP), a surface opposite to the surface bonded on the die bonding film of the above-described non pressure sensitive adhesive film was firmly fixed to a glass plate. Subsequently, a shearing force was applied to the die bonding film with the chip at a speed of 50 mm/minute using series 4000 produced by Dage Holdings Limited, and a shearing force at a point of time for the bonding film to be removed from the non pressure sensitive adhesive film with the chip was obtained.

(3) Evaluation in Manufacturing of Semiconductor Chip

The releasing film of each dicing and die bonding tape of Example and Comparative example was separated, and the separated and exposed die bonding film was laminated onto one surface of a silicon wafer (80 μm in thickness) with a diameter of 8 inch at a temperature of 60° C., obtaining evaluation samples.

The evaluation sample was diced into a chip size of 10 mm×10 mm at a feeding speed of 50 mm/second using a Dicing apparatus DFD 651 (manufactured by DISCO Corporation) Existence of jump of the chip in dicing was observed.

After dicing, a continuous pickup of the divided semiconductor chips was performed using a die bonder Bestem D-02 (manufactured by Canon Machinery Inc., under conditions of a collet size 8 mm square, a pushing up speed of 5 mm/second, and a bonding temperature of 100° C. In this way, evaluation of pickup was performed.

Following Table 1 illustrates the results.

TABLE 1

| | | | | Comp. | Comp. | Comp. |
|---|---|---|---|---|---|---|
| | Ex. 1 | Ex. 2 | Ex. 3 | Ex. 1 | Ex. 2 | Ex. 3 |
| Type of Non Pressure Sensitive | 6221FC | LDPE | HDPE | GF-8 | GF-8 | LINTEC D675 |
| Adhesive Film | | | | | Embossed | UV Treated |
| | | | | | Article | Article |
| Separation Strength (N/m) | 1.2 | 1.6 | 3.2 | 1.2 | 1.2 | 7.2 |
| Shear Strength (N/mm²) | 1.61 | 0.44 | 1.09 | 0.28 | 0.17 | 2.67 |
| Chip Jump in Dicing | Not | Not | Not | Observed | Observed | Not |
| | Observed | Observed | Observed | (Jump in | (Jump in | Observed |
| | | | | Peripheral | Whole | |
| | | | | Area) | Surface) | |
| Continuous Pickup Property | 0/100 | 0/100 | 0/100 | 2/100 | — | 2/2 |
| Number of | | | | | Evaluation | |
| Pickup Failure/Pickup Total | | | | | Impossible | |

### Example 4

A blended material was obtained by blending: G-2050M (manufactured by Nippon Oil & Fats Co., Ltd., an acrylic high molecular polymer including epoxy group, weight average molecular weight Mw 200,000) 15 parts by weight; EXA-7200HH (manufactured by DIC Corporation, dicyclopentadiene type epoxy resin) 70 parts by weight; HP-4032D (manufactured by DIC Corporation, naphthalene type epoxy resin) 15 parts by weight; YH-309 (manufactured by Japan Epoxy Resins Co., Ltd., acid anhydride curing agent) 38 parts by weight; 2MAOK-PW (manufactured by Shikoku Chemicals Corporation, imidazole) 8 parts by weight; S320 (manufactured by Chisso Corp., aminosilane) 2 parts by weight; and MT-10 (manufactured by Tokuyama Corp., surface hydrophobed fumed silica) 4 parts by weight. Methyl ethyl ketone (MEK) as a solvent was added to the blended material to give 60% of solid content. Then the mixture was agitated to obtain a coating liquid. This coating liquid was applied so as to give a thickness of 40 μm on a releasing film, and was dried by heating in an oven for 3 minutes at 110° C. to give a die bonding film formed on the releasing film.

Next, as a non pressure sensitive adhesive film an LLDPE1 (manufacturing method: inflation method, used LLDPE of molecular weight 80000, LLDPE film, and 50 μm in thickness) was prepared. This LLDPE1 was bonded onto a surface of the die bonding film opposite to a surface having a releasing film bonded thereto.

After the laminated material was cut into a circular shape, PE tape #6318-B as a dicing film (pressure sensitive adhesive film manufactured by Sekisui Chemical Co., Ltd., a rubber pressure sensitive adhesive layer having a thickness of 10 μm is formed on one side of a polyethylene substrate having a thickness of 70 μm) was applied from the pressure sensitive adhesive layer side onto the surface of the LLDPE1 opposite to the surface having the die bonding film bonded thereto. The dicing film obtained was cut into a larger circular shape than the size of the die bonding film. In this way, a dicing and die bonding tape in 4 layers having releasing film/die bonding film/LLDPE1 (non pressure sensitive adhesive film)/dicing film laminated in this sequential order was manufactured.

### Example 5

As a non pressure sensitive adhesive film, an LLDPE2 (manufacturing method: T-die method, used LLDPE of molecular weight 80000, LLDPE film, and 50 μm in thickness) was prepared. Except for having used LLDPE2 for non pressure sensitive adhesive film instead of the LLDPE1, the same method as that of Example 4 was repeated to manufacture a dicing and die bonding tape in 4 layers.

### Example 6

As a non pressure sensitive adhesive film, a PP (manufacturing method: T-die method, manufactured by Prime Polymer Co., Ltd., and used raw materials of J715M, polypropylene film, and 50 μm in thickness) was prepared. Except for having used the above-described PP instead of the LLDPE1 as a non pressure sensitive adhesive film, the same method as that of Example 4 was repeated to manufacture a dicing and die bonding tape in 4 layers.

### Example 7

As a non pressure sensitive adhesive film, an HDPE film (manufacturing method: T-die method, manufactured by Prime Polymer Co., Ltd., and used raw materials of 3300F, HDPE film, and 50 μm in thickness) was prepared. Except for having used the above-described HDPE film instead of the LLDPE1 as a non pressure sensitive adhesive film, the same method as that of Example 4 was repeated to manufacture a dicing and die bonding tape in 4 layers.

### Referential Example

As a non pressure sensitive adhesive film, a PBT film (manufacturing method: T-die method, OT film manufactured by Sekisui Chemical Co., Ltd., polybutylene terephthalate film, and 50 μm in thickness) was prepared. Except for having used a PBT film instead of the LLDPE1 as a non pressure sensitive adhesive film, the same method as that of Example 4 was repeated to manufacture a dicing and die bonding tape in 4 layers.

Evaluation of Examples 4 to 8

(1) Evaluation of Non Pressure Sensitive Adhesive Film

The non pressure sensitive adhesive film was measured for an elongation and a stress at a point of tensile rupture in MD and TD under a condition of tensile speed of 300 mm/minute using RTC-1310A produced by ORIENTEC Co., LTD. according to JIS K 7127.

Furthermore, the non pressure sensitive adhesive film was measured for a modulus of elasticity at a room temperature (23° C.) in MD and TD, using RTC-1310A produced by ORIENTEC Co., LTD. according to JIS K 7127.

(2) Evaluation of Cutting Ability in Manufacturing Of a Semiconductor Chip

The same method as in the evaluation in Examples 1 to 3 was repeated to evaluate the cutting ability in manufacturing of a semiconductor chip. Here, the cutting ability in pickup was evaluated by the following evaluation criteria.

Evaluation Criteria of Cutting Ability

◯: Hairy cutting waste was hardly observed in dicing; or even if hairy cutting waste existed, hairy cutting waste was in a level hardly providing problem to pickup.
Δ: Hairy cutting waste might occur, leading to possible pickup failure.
X: Hairy cutting waste was observed in a large number of chips, and pickup failure occurred at remarkable proportion.

Following Table 2 illustrates the results.

TABLE 2

| | Type of | | | | | | |
|---|---|---|---|---|---|---|---|
| | Non Pressure | Evaluation of Non Pressure Sensitive Adhesive Film | | | | | |
| | Sensitive | Measurement | | | Modulus of | Separation | Cutting |
| | Adhesive Film | Direction | Elongation (%) | Stress (MPa) | Elasticity (MPa) | Power (N/m) | Ability |
| Ex. 4 | LLDPE1 | MD | 800 | 27 | 331 | 1.24 | ◯ |
| | | TD | 930 | 28 | 416 | | |
| Ex. 5 | LLDPE2 | MD | 850 | 31 | 233 | 1.36 | ◯ |
| | | TD | 950 | 30 | 224 | | |
| Ex. 6 | PP | MD | 735 | 28 | 512 | 1.36 | ◯ |
| | | TD | 720 | 24 | 433 | | |
| Ex. 7 | HDPE | MD | 970 | 40 | 533 | 1.32 | ◯ |
| | | TD | 1160 | 35 | 675 | | |
| Ex. 8 | PBT | MD | 735 | 75 | 1278 | 1.52 | Δ |
| | | TD | 720 | 70 | 1291 | | |

FIG. 11 illustrates the measured results of the non pressure sensitive adhesive films used in Example 4 and Referential example in plotting for elongations and stresses in a point of tensile rupture in MD. FIG. 12 illustrates the measured results of the non pressure sensitive adhesive films used in Examples and Comparative examples in plot for elongations and stresses in a point of tensile rupture in TD. In FIGS. 11 and 12, the area enclosed by the dotted lines designates a range of elongation of not less than 580% and not more than 1200%, and stress of not less than 15 MPa and not more than 65 MPa. The area enclosed with alternate long and short dash line designates a range of elongation of not less than 580% and not more than 1050%, and a stress of not less than 15 MPa and not more than 46 MPa.

### Examples 9 to 13, Comparative Example 4

(1) Formation of Pressure Sensitive Adhesive Layer

A blended material was obtained by blending: G-2050M (manufactured by Nippon Oil & Fats Co., Ltd., an acrylic high molecular polymer including epoxy group, weight average molecular weight Mw 200,000) 15 parts by weight; EXA-7200HH (manufactured by DIC Corporation, dicyclopentadiene type epoxy resin) 80 parts by weight; HP-4032D (manufactured by DIC Corporation, naphthalene type epoxy resin) 15 parts by weight; YH-309 (manufactured by Japan Epoxy Resins Co., Ltd., acid anhydride curing agent) 35 parts by weight; 2MAOK-PW (manufactured by Shikoku Chemicals Corporation, imidazole) 8 parts by weight; and S320 (manufactured by Chisso Corp., aminosilane) 2 parts by weight. Methyl ethyl ketone (MEK) as a solvent was added to the blended material to give 60% of solid content. Then the mixture was agitated to obtain a coating liquid. This coating liquid was applied on a releasing film, and was dried by heating in an oven for 3 minutes at 110° C. to give a pressure sensitive adhesive layer (40 μm in thickness) was formed on the releasing film.

(2) Formation of Non Pressure Sensitive Adhesive Film

First, the following acrylic polymer was synthesized.

(Polymer 1)

A solution was obtained by dissolving into ethyl acetate: butyl acrylate 79 parts by weight; ethyl acrylate 15 parts by weight; acrylic acid 1 part by weight; 2-hydroxyethyl acrylate 5 parts by weight; IRGACURE 651 (manufactured by Ciba-Geigy Corporation, 50% ethyl acetate solution) 0.2 parts by weight; and lauryl mercaptan 0.01 parts by weight. This solution was irradiated with ultraviolet rays to perform polymerization and an acrylic copolymer (polymer 1) with a weight average molecular weight 700,000 was obtained.

(Polymer 2)

A solution was obtained by dissolving into ethyl acetate: isobornyl acrylate 40 parts by weight; ethyl acrylate 54 parts by weight; acrylic acid 1 part by weight; 2-hydroxyethyl acrylate 5 parts by weight; IRGACURE 651 (manufactured by Ciba-Geigy Corporation, 50% ethyl acetate solution) 0.2 parts by weight; and lauryl mercaptan 0.01 parts by weight. This solution was irradiated with ultraviolet rays to perform polymerization and an acrylic copolymer (polymer 2) with a weight average molecular weight 700,000 was obtained.

Next, each component given in the following Table 3 was dissolved in ethyl acetate to be coated on a releasing PET using an applicator. Then the coated layers were dried by heating for 3 minutes in an oven at 110° C., obtaining non pressure sensitive adhesive films L1 to L4 having a thickness of 50 μm.

(3) Dicing Tape Layer

The following materials were prepared as a dicing tape layer.

Dicing tape 1 (referred to as DC1 in the following Table 3)

PE tape #6318-B: manufactured by Sekisui Chemical Co., Ltd., 70 μm in thickness, substrate polyethylene, 10 μm of rubber type pressure sensitive adhesive

Dicing tape 2 (referred to as DC2 in the following Table 3)

Adwill D650: UV type dicing tape manufactured by Lintec Corporation

Dicing tape 3 (referred to as DC3 in the following Table 3)

Elegrip UHP-0805MC: manufactured by DENKI KAGAKU KOGYO K.K., total thickness of 85 μm, 5 μm of pressure sensitive adhesive layer

(4) Manufacture of Dicing and Die Bonding Tape

On the surface of the pressure sensitive adhesive layer of the obtained releasing films, either of the obtained non pressure sensitive adhesive films L1 to L4 was laminated at 60° C. Subsequently, either of dicing tapes 1 to 3 (DC1 to 3) was applied as a dicing tape layer on the surface opposite to a surface having the pressure sensitive adhesive layer of the non pressure sensitive adhesive film bonded thereto. In application, when the dicing tape layer had the pressure sensitive adhesive layer, application was performed from a side facing the pressure sensitive adhesive layer. In this way, the dicing and die bonding tapes having layers laminated in the sequential order of releasing film/pressure sensitive adhesive layer/non pressure sensitive adhesive film/dicing tape layer.

### Comparative Example 5

Except for having applied materials rendered non pressure sensitive adhesive with photo-curing of the above-described dicing tape 2, in place of the non pressure sensitive adhesive film and the dicing tape layer laminated in Examples 9 to 13 and Comparative example 4, onto the surface of the pressure sensitive adhesive layer on the releasing film as the non pressure sensitive adhesive film and the dicing tape layer, the same method as the method in Examples 9 to 13 and Comparative example 4 was repeated, manufacturing the dicing and die bonding tapes having layers laminated in the sequential order of releasing film/pressure sensitive adhesive layer/non pressure sensitive adhesive film (dicing tape layer).

Evaluation of Dicing and Die Bonding Tape

(1) Measurement of Surface Energy

A surface where the pressure sensitive adhesive layer of non pressure sensitive adhesive film is to be bonded was measured for a surface energy, using a wettability reagent (manufactured by Nacalai Tesque, Inc.) according to JIS K 6798.

(2) Evaluation in Manufacturing of Semiconductor Chip

The same method as the method in evaluation of Examples 1 to 3 was repeated, and pickup property was evaluated as evaluation in manufacturing of semiconductor chips.

Furthermore, after pickup, 5 picked-up semiconductor chips were evaluated for omitted cut of a part of the pressure sensitive adhesive layer for every 4 sides and a total of 20 sides. The number of sides without omitted cut of the pressure sensitive adhesive layer larger than 50 μm were counted.

Following Table 3 illustrates the results.

TABLE 3

| | | | | | | | Comp. | Comp. |
|---|---|---|---|---|---|---|---|---|
| | | Ex. 9 | Ex. 10 | Ex. 11 | Ex. 12 | Ex. 13 | Ex. 4 | Ex. 5 |
| Non Pressure Sensitive Adhesive Film Type | | L1 | L1 | L1 | L2 | L3 | L4 | DC2 *2 |
| Non Pressure | Polymer 1 | 100 | 100 | 100 | 100 | 100 | — | — |
| Sensitive | Polymer 2 | — | — | — | — | — | 100 | — |
| Adhesive Film | U324A *1 | 2 | 2 | 2 | 2 | 20 | 2 | — |
| Blending Ratio | IRGACURE 651 *1 | 1 | 1 | 1 | 1 | 1 | 1 | — |
| (parts by weight) | SE4050 *1 | — | — | — | 50 | 150 | — | — |

| | | | | | | | |
|---|---|---|---|---|---|---|---|
| Dicing Tape Layer Type | DC1 | DC2 | DC3 | DC1 | DC1 | DC1 | DC2 *2 |
| Surface Energy of Non Pressure Sensitive Adhesive Film (N/m) | 32 | 32 | 32 | 35 | 39 | 41 | 45 |
| Separation Power of Die Attaching Film and | 3.2 | 3.2 | 3.2 | 2.8 | 2.4 | 6.4 | 140 |
| Non Pressure Sensitive Adhesive Film (N/m) | | | | | | | |
| Rate of Success of Pickup | 100/100 | 100/100 | 100/100 | 100/100 | 100/100 | 85/100 | 0/1 |
| (Number of Pickup Success)/(Pickup Total Number) | | | | | | | |
| Existence of Omission of Pressure Sensitive Adhesive Layer After Pickup | 20/20 | 20/20 | 20/20 | 20/20 | 20/20 | 8/20 | — |
| (Number of Sides wthout Omitted Cut)/ | | | | | | | |
| (Total of Evaluated Sides) | | | | | | | |

*1 U324A (Manufactured by Shin-Nakamura Chemical Co., Ltd.); IRGACURE (Manufactured by Ciba-Geigy Corporation); SE4050 (Manufactured by Admatechs)
*2 Layer Obtained by Photo-Curing of DC2 was Used by Single Layer as Non Pressure Sensitive Adhesive Film and Dicing Tape Layer.

### Examples 14 to 20 and Comparative Examples 6 to 7

Films including the acrylic resin composition having an acrylic polymer of either of the acrylic polymers 1 to 5 given in the following Table 4 as a principal component were prepared as the non-pressure sensitive adhesive layer 4.

TABLE 4

| | | Acid Value |
|---|---|---|
| | Weight Molecular Weight | (mgKOH/g) |
| Acrylic Polymer 1 | 700000 | 0.86 |
| Acrylic Polymer 2 | 760000 | 6.73 |
| Acrylic Polymer 3 | 890000 | 0.58 |
| Acrylic Polymer 4 | 730000 | 0.34 |
| Acrylic Polymer 5 | 920000 | 1.00 |
| Acrylic Polymer 6 | 260000 | 0.60 |

Here, the following compounds were prepared as a material for form the above-described acrylic resin compositions.

Photopolymerization initiator: IRGACURE 651 (manufactured by Ciba Speciality Chemicals)

Fillers

SC4050: Product made by Admatechs, silica fillers, average particle diameter: 1 μm;

SC2050: Product made by Admatechs, silica fillers, average particle diameter: 0.5 μm;

SC1050: Product made by Admatechs, silica fillers, average particle diameter: 0.3 μm

(oligomer)

U324A: Urethane acrylic oligomer manufactured by Shin-Nakamura Chemical Co., Ltd., (urethane acrylic oligomer with functionality of 10);

UA340P: Urethane acrylic oligomer, manufactured by Shin-Nakamura Chemical Co., Ltd. (bifunctional),

UN7600: Urethane acrylic oligomer, manufactured by Negami Chemical industrial co., Ltd. (bifunctional);

UN7700: Urethane acrylic oligomer, manufactured by Negami Chemical industrial co., Ltd. (bifunctional);

EBECRYL12: Polypropylene glycol tri acrylate, manufactured by DAICEL-CYTEC Company LTD.

### Example 14

An acrylic resin composition obtained by blending the above-described acrylic polymer 1 of 100 parts by weight, IRGACURE 651 of 1 part by weight, and U324A 15 parts by weight as a urethane acrylic oligomer was irradiated with a light by 2 of mercury-vapor lamps having 160 W of energy to be cured, obtaining the non pressure sensitive adhesive film 4. The non pressure sensitive adhesive film 4 obtained in this way was measured for the storage elastic modulus and tensile elongation at a temperature of 23 that is a temperature in pickup of semiconductor chips, by the following methods.

1) Storage Elastic Modulus

A completely cured non pressure sensitive adhesive film 4 with 0.5 mm of thickness and 5 mm of width was cut into a width of 3 cm, and was measured for a storage elastic modulus at 23° C., under conditions of 10 Hz and 0.1% of distortion using DVA-200 produced by IT Measurement Company.

2) Tensile Elongation

A completely cured non pressure sensitive adhesive film 4 with 0.5 mm of thickness, 5 mm of width, and 7 cm of length was tested, under a condition of 300 mm/minute, using a tensile testing machine AG-IS (made by Shimadzu Corporation), and measured for a tensile elongation at which the sample was broken.

A dicing and die bonding tape was manufactured in the following manner using the above-described non pressure sensitive adhesive film 4. A blended material was obtained by blending: G-2050M (manufactured by Nippon Oil & Fats Co., Ltd., an acrylic high molecular polymer including epoxy group, weight average molecular weight Mw 200,000) 15 parts by weight; EXA-7200HH (manufactured by DIC Corporation, dicyclopentadiene type epoxy resin) 70 parts by weight; HP-4032D (manufactured by DIC Corporation, naphthalene type epoxy resin) 15 parts by weight; YH-309 (manufactured by Japan Epoxy Resins Co., Ltd., acid anhydride curing agent) 38 parts by weight; 2MAOK-PW (manufactured by Shikoku Chemicals Corporation, imidazole) 8 parts by weight; S320 (manufactured by Chisso Corp., aminosilane) 2 parts by weight; and MT-10 (manufactured by Tokuyama Corp., surface hydrophobed fumed silica) 4 parts by weight. Methyl ethyl ketone (MEK) as a solvent was added to the blended material to give 60% of solid content. Then the mixture was agitated to obtain a coating liquid. This coating liquid was applied so as to give a thickness of 40 μm on a releasing film, and was dried by heating in an oven for 3 minutes at 110° C. to give a pressure sensitive adhesive layer 3 formed on the releasing film.

The above-described non pressure sensitive adhesive film 4 was laminated onto a surface opposite to the surface facing the releasing film of the pressure sensitive adhesive layer 3 at 60° C., obtaining a laminated material. After the laminated material was cut into a circular shape, onto a surface opposite to the surface facing the pressure sensitive adhesive layer 3 of the non-pressure sensitive adhesive layer 4 (sheet), PE tape #6318-B as a dicing film (pressure sensitive adhesive film manufactured by Sekisui Chemical Co., Ltd., a rubber pressure sensitive adhesive layer having a thickness of 10 μm is formed on one side of a polyethylene substrate having a thickness of 70 μm) was applied from the pressure sensitive adhesive layer side. The dicing film obtained was cut into a circular shape larger than the size of the pressure sensitive adhesive layer 3. In this way, a dicing and die bonding tape in 4 layers having releasing film/pressure sensitive adhesive layer 3/non pressure sensitive adhesive film 4/dicing film laminated in this sequential order was manufactured.

### Examples 15 to 20

As shown in Table 5, except for having changed the type and the blending proportion of the materials that form the non pressure sensitive adhesive film 4, the same method as the method in Example 14 was repeated, and non pressure sensitive adhesive films 4 were obtained. Here, the filler was blended in Examples 15, 16, 17, 18, and 20, the urethane acrylic oligomer was not blended in Example 17, and the filler and the urethane acrylic oligomer were not blended in Example 19. A polyether skeleton acrylic oligomer was blended in Example 20.

### Comparative Examples 9 to 14

As illustrated in the above-described Table 4, the same method as the method in Example 13 was repeated except for having changed the materials and blending proportions that were used for formation of the non pressure sensitive adhesive film 4 including the acrylic resin composition, obtaining the non pressure sensitive adhesive film 4 for evaluation.

As the non pressure sensitive adhesive film, films including acrylic resin compositions having either of the acrylic polymer of acrylic polymers 1 to 5 given in the Table 4 as a principal component was prepared.

Evaluation of Examples 14 to 20 and Comparative Examples 6 to 7

Following Table 5 gives measurement results of the modulus of elasticity and the tensile elongation at 23° C. of each non pressure sensitive adhesive film as mentioned above.

The same method as the method of evaluation in Examples 1 to 3 was repeated, and the obtained dicing and die bonding tapes were measured for the separation strength between the non pressure sensitive adhesive film and the die bonding film. Following Table 5 shows the results.

Furthermore, evaluation in manufacturing of semiconductor chips were performed in the following manner. The releasing film of each dicing and die bonding tape of Example and Comparative example was separated, and the separated and exposed die bonding film was laminated onto one surface of a silicon wafer (80 μm in thickness) with a diameter of 8 inch at a temperature of 60° C., obtaining evaluation samples.

The evaluation sample was diced into a chip size of 10 mm×10 mm at a feeding speed of 50 mm/second using a Dicing apparatus DFD 651 (manufactured by DISCO Corporation) Existence of jump of the chip in dicing was observed. Table 5 shows the results. Details of evaluation symbol in Table 5 will be shown hereinafter.

◯: no hairy cutting waste, no chip-jump, no crack observed
Δ: either one of chip jump, hairy cutting waste, and crack observed
X: not less than 2 of chip jump, hairy cutting waste, crack observed

After dicing, a continuous pickup of the divided semiconductor chips was performed using a die bonder Bestem D-02 (manufactured by Canon Machinery Inc.) under conditions of a collet size 8 mm square, a pushing up speed of 5 mm/second, and a pickup temperature of 23° C. In this way, evaluation of pickup was performed. Following Table 5 shows the results. Details of evaluation symbol in Table 5 will be shown hereinafter.

◯: Proportion of continuous pickup NG is 0%
Δ: Proportion of continuous pickup NG is 1 to 15%
X: Proportion of continuous pickup NG is not less than 16%

TABLE 5

| | | | | | | | | | Comp. | Comp. |
|---|---|---|---|---|---|---|---|---|---|---|
| | | Ex. 14 | Ex. 15 | Ex. 16 | Ex. 17 | Ex. 18 | Ex. 19 | Ex. 20 | Ex. 6 | Ex. 7 |
| Acrylic Polymer 1 | | 100 | 100 | 100 | 100 | | | 100 | | |
| Acrylic Polymer 2 | | | | | | | | | | 100 |
| Acrylic Polymer 3 | | | | | | 100 | 100 | | | |
| Acrylic Polymer 4 | | | | | | | | | | |
| Acrylic Polymer 5 | | | | | | | | | | |
| Acrylic Polymer 6 | | | | | | | | | 100 | |
| IRGACURE 651 | Ciba Specialty Chemicals | 1 | 1 | 1 | 1 | 1 | 1 | 1 | 1 | 1 |
| SC4050 | Admatechs | | 50 | 50 | 50 | | | | | |
| SC2050 | Admatechs | | | | | 50 | | 50 | | |
| SC1050 | Admatechs | | | | | | | | | |
| U324A | Shin-Nakamura Chemical Co., Ltd. | 15 | 15 | | | | | | | 2 |
| UA340P | Shin-Nakamura Chemical Co., Ltd. | | | 15 | | | | | | |
| UN7600 | Negami Chemical Industrial Co., Ltd. | | | | | | | | | |
| UN7700 | Negami Chemical Industrial Co., Ltd. | | | | | 15 | | | | |
| EBECRYL12 | DAICEL-CYTEC CO., LTD. | | | | | | | 15 | | |
| Modulus of | MPa | 30 | 70 | 12 | 20 | 2 | 6 | 50 | 169 | 50 |
| Elasticity | | | | | | | | | | |
| Tensile | % | 9 | 13 | 45 | 30 | 38 | 38 | 17 | 24 | 18 |
| Elongation | | | | | | | | | | |
| Separation | N/m | 6 | 5 | 3 | 4 | 4 | 5 | 5 | 16 | 8 |
| Strength | | | | | | | | | | |
| DC | | Δ | ◯ | ◯ | ◯ | ◯ | ◯ | ◯ | Δ | ◯ |
| PU | % | ◯ | ◯ | ◯ | ◯ | ◯ | ◯ | ◯ | Δ | Δ |

Number of NG of PU ◯: 1% Δ: 0 to 16% X: Not Less than 16%
DC Designates Chip Jump Evaluation at the Time of Dicing. PU Designates Evaluation at the Time of Pickup.

### Example 21

The non pressure sensitive adhesive film component prepared in Example 15 was blended by the same method as the method in Example 15, and the blend was irradiated with UV light as in Example 15 to be cured, obtaining a non pressure sensitive adhesive film.

The composition for die bonding used in Example 15 was coated on the surface of the above-described non pressure sensitive adhesive film so as to give a thickness of 20 μm. On the surface of this die bonding film, a releasing film was further laminated as in Example 15. Then, item number 6318-B manufactured by Sekisui Chemical Co., Ltd., as a dicing tape, was applied from the pressure sensitive adhesive layer side as in Example 15 onto the surface of the outside of the above-described non pressure sensitive adhesive film of the laminated product of the above-described die bonding film and the non pressure sensitive adhesive film, obtaining a dicing and die bonding tape.

Next, after separating the release film of the above-described dicing and die bonding tape, a semiconductor wafer having a diameter of 8 inches and a thickness of 30 μm was laminated onto the surface of the die bonding film at 60° C., obtaining a sample for dicing.

### Comparative Example 8

Except for having used the composition for the non pressure sensitive adhesive films prepared in Example 21 as a film having a thickness of 50 μm untreated without irradiation with UV light, the same method as the method in Example 20 was repeated, obtaining a dicing and die bonding tape.

(Evaluation of Example 21 and Comparative Example 8)

The above-described semiconductor wafer was irradiated with a laser, using a laser device (produced by DISCO Corporation and type number:DFL7160), under conditions of a laser beam having a wavelength (third harmonic generation of Nd-YAG laser) of 355 nm, a diameter of focus of 6 μm, and output 5.2 W, performing dicing at 400 mm/second in cut speed.

Pickup of the semiconductor chips together with the die bonding film was performed from the samples diced as described above. In Example 21, the semiconductor chip with the die bonding film bonded thereto was able to be separated promptly, and was able to be removed from the non pressure sensitive adhesive film. Here, when street part exposed was observed with an optical microscope (manufactured by KEYENCE CORP. type number: VHX) after die bonding, it was confirmed that the cut plane was clean.

On the contrary, when the semiconductor chip obtained by dicing was picked up together with the die bonding film in the similar dicing in Comparative example 8, this operation provided cracks to the semiconductor wafer. Therefore, the semiconductor chip was not able to be picked up together with the die bonding film. Here, observation of the condition of the street part exposed by dicing has clarified that the adhesive of the releasing film wrapped around the side face of the semiconductor chip, leading to obstruction of pickup.

1. A dicing and die bonding tape used in dicing of a wafer, in obtaining a semiconductor chip and in die bonding of the semiconductor chip,
the dicing and die bonding tape comprising:
a die bonding film; and
a non pressure sensitive adhesive film bonded on one surface of the die bonding film,
a separation strength between the die bonding film and the non pressure sensitive adhesive film being within a range of 1 to 6 N/m, a shear strength between the die bonding film and the non pressure sensitive adhesive film being 0.3 to 2 N/mm².

2. The dicing and die bonding tape according to claim 1, wherein an elongation in a point of tensile rupture of the non pressure sensitive adhesive film is within a range of 10 to 100%, or within a range of 580 to 1200%.

3. The dicing and die bonding tape according to claim 1 or 2, wherein a modulus of elasticity of the non pressure sensitive adhesive film at a temperature in pickup is within a range of 1 to 400 MPa.

4. The dicing and die bonding tape according to claim 1, wherein a storage elastic modulus of the non pressure sensitive adhesive film at a temperature in pickup is within a range of 1 to 400 MPa, and an elongation in a point of tensile rupture is within a range of 5 to 100%.

5. The dicing and die bonding tape according to claim 1 or 2, wherein a surface energy of a surface bonded on the die bonding film of the non pressure sensitive adhesive film is not more than 40 N/m.

6. The dicing and die bonding tape according to claim 1 or 2, wherein the non pressure sensitive adhesive film consists of a cured substance by cross-linking of a curable resin composition.

7. The dicing and die bonding tape according to claim 1, wherein a principal component of the non pressure sensitive adhesive film is a (meth)acrylic ester polymer having an alkyl group therein, a carbon number of the alkyl group being 1 to 18.

8. The dicing and die bonding tape according to claim 7, wherein an acid value of the (meth)acrylic acid ester polymer is not more than 2.

9. The dicing and die bonding tape according to claim 7, further comprising an oligomer having a double-bonding functional group that is reactive with an acrylic group, a weight average molecular weight of the oligomer being in a range of 1000 to 50000, a glass transition temperature Tg being not more than 25° C.

10. The dicing and die bonding tape according to claim 9, wherein the oligomer is blended at a proportion of 1 to 100 parts by weight to the (meth)acrylic acid ester polymer 100 parts by weight.

11. The dicing and die bonding tape according to claim 9, wherein the oligomer is an acrylic oligomer having one kind of skeleton selected from a group consisting of polyether skeleton, polyester skeleton, butadiene skeleton, polyurethane skeleton, silicate skeleton, and dicyclopentadiene skeleton.

12. The dicing and die bonding tape according to claim 11, wherein the acrylic oligomer has acrylic groups at both ends of the molecule thereof.

13. The dicing and die bonding tape according to claim 11, wherein the acrylic oligomer is an urethane acrylic oligomer having 3 to 10 of functionality.

14. The dicing and die bonding tape according to claim 1 or 2, wherein the non pressure sensitive adhesive film further includes filler particles having an average particle diameter of 0.1 to 10 μm.

15. The dicing and die bonding tape according to claim 1 or 2, wherein the non pressure sensitive adhesive film has a two-layered structure having a first and a second layers laminated thereon.

16. The dicing and die bonding tape according to claim 15, wherein the first layer of the non pressure sensitive adhesive film is a layer having a low modulus of elasticity, the modulus of elasticity being 1 to 1000 MPa at 23° C.

17. The dicing and die bonding tape according to claim 16, wherein the layer having a low modulus of elasticity is formed using a material including an acrylic resin or a silicone resin.

18. The dicing and die bonding tape according to claim 1, wherein a dicing film is bonded on a surface opposite to a surface having the die bonding film of the non pressure sensitive adhesive film bonded thereto.

19. The dicing and die bonding tape according to claim 1 or 2, wherein the die bonding film consists of a composition including an epoxy compound, a macromolecule polymer having an epoxy group, and an acid anhydride curing agent.

20. A method for manufacturing a semiconductor chip, the method comprising:
a step of preparing a dicing and die bonding tape according to claim 1 or 2, and a semiconductor wafer;
a step of bonding the semiconductor wafer on a surface opposite to a surface of the die bonding film having the non pressure sensitive adhesive film bonded thereto of the dicing and die bonding tape;
a step of dicing the semiconductor wafer together with the die bonding film to divide the semiconductor wafer into an individual semiconductor chip; and
a step of separating the semiconductor chip having the die bonding film bonded thereto from the non pressure sensitive adhesive film after the dicing to pick up the semiconductor chip together with the die bonding film.

21. The method for manufacturing a semiconductor chip according to claim 20, wherein the semiconductor chip is picked up, while avoiding variation of a separation force between the die bonding film and the non pressure sensitive adhesive film, after the dicing.
